(19) United States
(12) Patent Application Publication
(10) Pub. No.: US 2026/0150213 A1
(43) Pub. Date: May 28, 2026

(54) LAYERED CABLE ROUTING FOR NETWORK SWITCHES

(71) Applicant: MELLANOX TECHNOLOGIES, LTD., Yokneam (IL)

(72) Inventors: Yaron Regev, Sde Itzzhak (IL); Samer Khory, Nof Haglil (IL); Alex Garmash, Nesher (IL); Ron Hartston, Alonei Aba (IL); Emanuel Fitoussi, Hadera (IL)

(21) Appl. No.: 18/960,074

(22) Filed: Nov. 26, 2024

(51) Int. Cl. H05K 7/02; H04Q 1/02; H05K 7/14; H05K 7/20

(52) U.S. Cl. CPC H05K 7/023; H04Q 1/035; H05K 7/1451; H05K 7/20009; H05K 7/20218

(57) ABSTRACT

Approaches presented herein provide for the connection of networking devices by routing network cable harnesses using layered transceiver panel structures and modular guides. Network cables can be connected to layered transceiver panels for transferring communications between external devices and a network switch. Modular guides can route the network cables from the layered transceiver panels, such as in a plane perpendicular to the plane of the layered transceiver panels. The network cables, connected to layered transceiver panels and routed through the modular guides, can then be connected to the network switch. The network switch can be liquid-cooled and/or air-cooled, with airflow passing through openings of the modular guides.

### TECHNICAL FIELD

This disclosure relates to layered cable routing for network switches, and in particular to the use of stackable circuits and corresponding routing guides to route network cable harnesses.

### BACKGROUND

Networking devices may use cabled connections to transfer communications with other devices, such as transceivers located in a server with a networking device. As capabilities of network devices and number of cabled connections for the devices increase, the number and volume of cables, or harnesses, used for the connections may also increase. For certain applications, such as a network switch, the connections may be positioned in multiple layers as well as in multiple directions and opposing ends of the cables may require different, intricate groupings, complicating installation. However, available space between the connections may be limited, such as within a server, which can make installation of the cables difficult. Additionally, the devices may need to be cooled, which can be obstructed by the mass of cables. There is a growing need for well-defined, repeatable cable paths and an ability to maintain cable groupings to provide consistently producible and space-effective network connections.

### BRIEF DESCRIPTION OF THE DRAWINGS

Various embodiments in accordance with the present disclosure will be described with reference to the drawings, in which:

FIGS. 1A-1C illustrate a top view of an example system for routing network cable, according to at least one embodiment;

FIG. 2A illustrates a perspective view of an example architecture of a transceiver panel structure for routing network cable, according to at least one embodiment;

FIG. 2B illustrates a perspective view of an example system including an architecture of a transceiver panel structure for routing network cable, according to at least one embodiment;

FIGS. 3A-3F illustrate an example combinable cable cassette sections for routing network cable, according to at least one embodiment;

FIGS. 4A-4E illustrate an example network cable routing assembly, according to at least one embodiment;

FIG. 5 illustrates an example process that can be used to route a plurality of cables in a server assembly, according to at least one embodiment;

FIG. 6 illustrates components of a distributed system that can be utilized to update or perform inferencing using a machine learning model, according to at least one embodiment;

FIG. 7A illustrates an example data center system, according to at least one embodiment;

FIG. 7B illustrates an example network architecture for a data center system, according to at least one embodiment;

FIG. 7C illustrates an example data center environment for a data center system, according to at least one embodiment;

FIG. 8 illustrates a computer system, according to at least one embodiment;

FIG. 9 illustrates a computer system, according to at least one embodiment;

FIG. 10 illustrates at least portions of a graphics processor, according to one or more embodiments; and

FIG. 11 illustrates at least portions of a graphics processor, according to one or more embodiments.

### DETAILED DESCRIPTION

In the following description, various embodiments will be described. For purposes of explanation, specific configurations and details are set forth in order to provide a thorough understanding of the embodiments. However, it will also be apparent to one skilled in the art that the embodiments may be practiced without the specific details. Furthermore, well-known features may be omitted or simplified in order not to obscure the embodiment being described.

Approaches in accordance with various embodiments are directed toward an assembly of stackable circuits and corresponding cable routing guides for bridging external devices to a network switch. The cable routing guides may be a layered cable routing. For each required layer of external facing ports cable bundles are wired to custom circuit boards through routing guides, the layers of wired circuit boards are stacked with the cable bundles further oriented using the routing guides, and the cable bundles are finally aligned toward the network switch connections using the routing guides. In one embodiment, the routing guides change the orientation of the cable bundles along three mutually perpendicular planes (e.g., XYZ coordinates) as needed to group and position the final connections. In some embodiments, a three-layer structure of three PCBs and a plastic cassette in a separate assembly from the switch are created. The switches are split in two sections (back section and front section) and the harnesses are rerouted outside the switch. The routing is performed at the PCB level. The braids are wired in three stages. The plastic parts of each layer are built in a way to allow routing the harnesses in clear paths and create repetition in every assembly and maintain required openings for air flow to cool the system. Without a three-layer assembly in a separate assembly, assembly would have been done by multiple reversals of the switch to connect the NCI connectors to the various ASICs. The assembly process would take a significant time. In at least one embodiment, systems and methods may be associated with an architecture of circuit board structures and composite routing cartridges to route layered network cable sets, such as harnesses or braids. Specifically, systems and methods are directed toward network switches, such as part of a server or server assembly, which can be connected using network cables to transfer communication signals. A layered circuit board structure can be paired with a layer of a composite routing cartridge and connect with network cable sets that are routed through the layer of a composite routing cartridge. In an example, the layered circuit board structures can receive communication inputs, such as from external devices connected to the circuit board structures, which are to be provided to the network switch. The composite routing cartridges can include a variety of modular pieces combinable to change one or more groupings and orientations of the network cables, or network cable braids, between one or more planes, such as perpendicular or parallel planes. Additional layered circuit board structures paired with additional layers of the composite routing cartridge and including layers of network cable sets can be stacked together as a unit. The cable sets can also be routed in a plane perpendicular to the plane of the stacked unit layers. The layered network cable sets routed from the stacked unit can then be connected to the network switch or devices on the network switch, such as Application-Specific Integrated Circuits (ASICs), enabling communication with the circuit board structures. The layered network cable sets can be routed, or pre-routed outside of a server assembly before the stacked unit is positioned inside of the server assembly and the routed cables are connected to the switch. In an embodiment, the layered circuit board structures and the composite routing cartridge may be used separately, without the other, to provide network cable to a device, such as a network switch.

Various systems and methods enable simplified cable routing for bridging external devices to a network switch for a compact space, which is especially useful in systems with a large number of connections. Certain embodiments may incorporate layered circuit boards that include ports, such as part of transceiver cages, to connect with the external devices that provide inputs to communicate with the network switch. This configuration enables harnesses to be routed in a way that allows reliability in production and high repeatability in the assembly process while not blocking the large air flow openings. This structure allows easy, fast, safe, and repeatable routing of the harnesses. At least one embodiment may be used with devices that provide liquid cooling or air cooling for the network switch and the layered circuit boards. Parts of the devices that provide liquid cooling can be positioned adjacent to the composite routing cartridge. The composite routing cartridge can include openings to allow airflow from the devices that province air cooling to pass between the layered circuit board structures and the network switch. In another embodiment, the network cable layers may be positioned through the composite routing cartridge as the modular pieces are combined. The composite routing cartridge can include features and/or separate sections to retain the network cable layers, such as in groups or in orientation changes. Systems and methods may therefore overcome problems with existing network cable routing techniques that often are not suitable for compact spaces or for repetitive use.

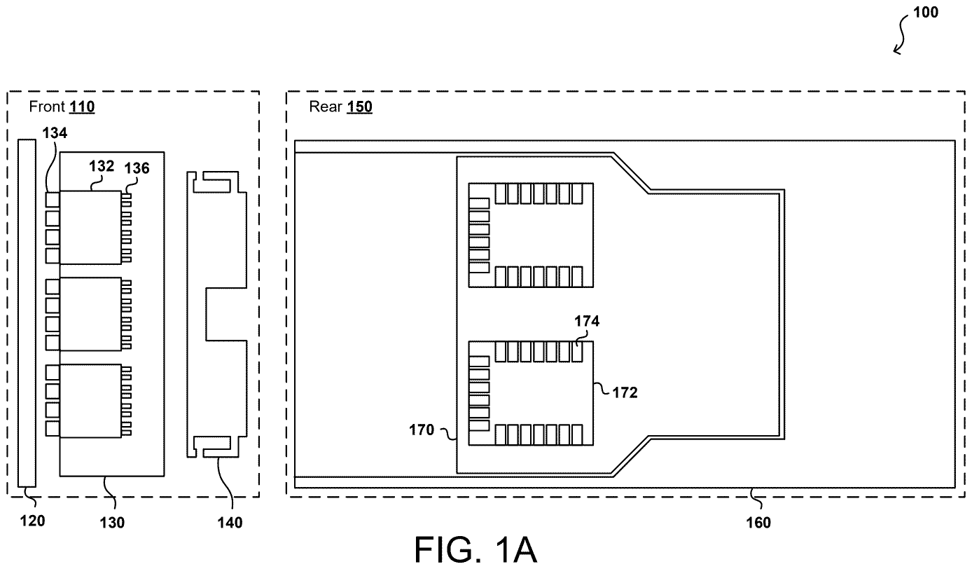

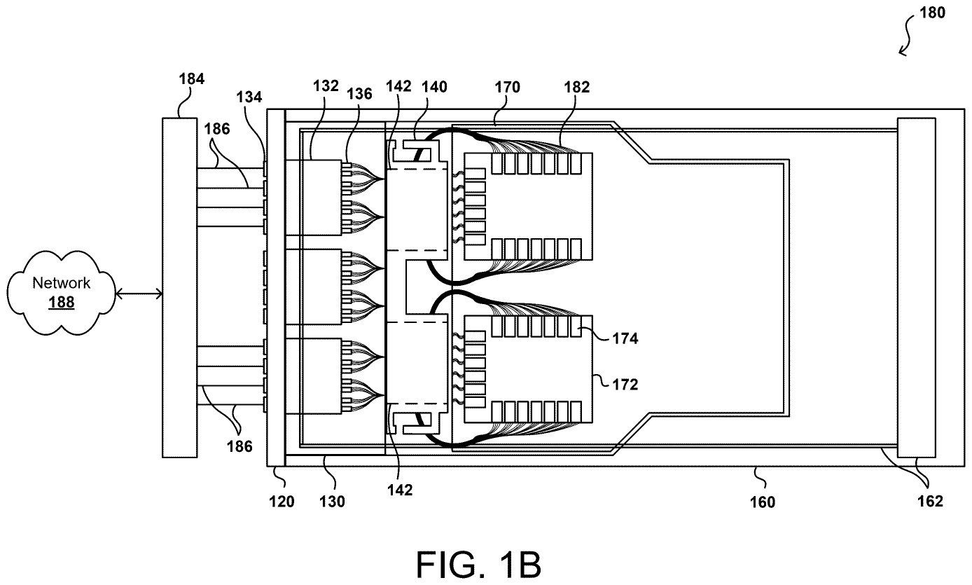

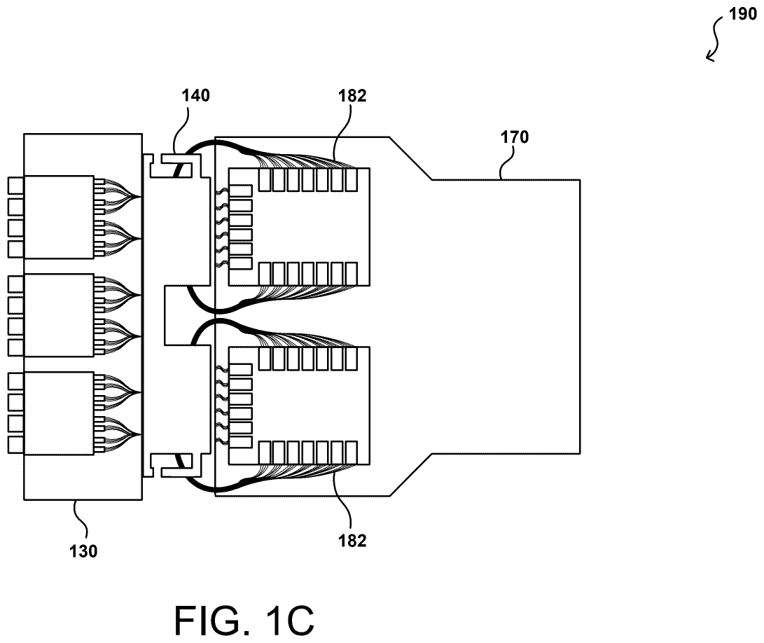

FIG. 1A illustrates a top view of an example system 100 for routing network cable, according to at least one embodiment. It should be appreciated that embodiments of the present disclosure may also be used with reference to other systems and that specific discussion of a particular system may be provided by way of non-limiting example and may include equivalents with other systems. Moreover, various features have been removed for clarity and conciseness. Additionally, systems and methods may be used with a variety of different architectures. In this example, the system 100 includes a server assembly front section 110 and a server assembly rear section 150. The front section 110 may include a front panel 120, one or more layered circuit boards 130, and one or more layers of a composite routing cartridge 140. The front panel 120 may be a fascia for the layered circuit boards 130 and/or the front section 110. In an embodiment, the front panel 120 may be used to secure the layered circuit boards 130 together, at least in part. The layered circuit boards 130 may include a plurality of external ports 134 to connect with external devices. The layered circuit boards 130 may include a plurality of internal ports 136 to connect with internal devices, such as through network cables. The layered circuit boards 130 may include transceiver cages 132 or other circuity which incorporate the external ports 134 and the internal ports 136, such as into transceivers. The composite routing cartridge 140 may be comprised of more than one section and may include a number of paths to route network cables. The composite routing cartridge 140 may be secured to the layered circuit boards 130, such as individual circuit boards secured to the layers of the composite routing cartridge 140 can be stacked together into a combined unit. In an example, the system 100 may have stacked three of the layered circuit boards 130 and three layers of the composite routing cartridge 140 corresponding to the each of the layered circuit boards 130. The individual layers of the corresponding composite routing cartridge 140 and the layered circuit boards 130 may have shared planes to receive network cables, such as stacked parallel planes.

The rear section 150 may include a server tray 160 or box and a network switch 170. The server tray 160 may be part of a larger system, such as a server rack and may be used to retain the network switch and the front section 110. In an embodiment, the server tray 160 may have structural resilience to support the front section 110 and the network switch 170, such as being composed of sheet metal. The network switch 170 may include one or more network cards 172 or chips, such as ASICs, network interface controllers (NICs), printed circuit boards (PCBs), or other suitable devices. In an example, the network switch 170 may have two of the network cards 172 on two separate planes, such as where the planes are stacked in parallel, for four total of the network cards 172. The network cards 172 may include a plurality of switch ports 174 to connect with internal devices, such as through network cables. In an embodiment, the front section 110 may be able to slide into the server tray 160 so that network cables connected to the layered circuit boards 130 and pre-routed through the composite routing cartridge 140 can be connected to the network switch 170.

Although the term “circuitry” as used herein with respect to the layered circuit boards 130 is described in some cases using functional language, it should be understood that the particular implementations necessarily include the use of particular hardware configured to perform the functions associated with the respective circuitry as described herein. It should also be understood that certain of these layered circuit boards 130 may include similar or common hardware. For example, two sets of circuitries may both leverage use of the same processor, network interface, storage medium, or the like to perform their associated functions, such that duplicate hardware is not required for each set of circuitries. It will be understood in this regard that some of the components described in connection a circuit may be housed together, while other components are housed separately (e.g., circuity which incorporate the external ports 134 and the internal ports 136). While the term “circuitry” should be understood broadly to include hardware, in some embodiments, the term “circuitry” may also include software for configuring the hardware. For example, in some embodiments, “circuitry” may include processing circuitry, storage media, network interfaces, input/output devices, and the like. In some embodiments, other elements of a circuit may provide or supplement the functionality of particular circuitry.

FIG. 1B illustrates a top view of an example system 180 for routing network cable, according to at least one embodiment. In this example, the system 100 illustrated in FIG. 1A can be used to incorporate network cable sets 182 and affix the server assembly front section 110 with the server assembly rear section 150 as a planarized system, such as part of a network 188. The system 180 includes the front panel 120 positioned and affixed over at least a portion of the layered circuit boards 130. The system 180 includes the network cable sets 182 connected to the internal ports of the layered circuit boards 130, routed through the composite routing cartridge 140, and connected to the network switch 170. The plurality of external ports 134 of the layered circuit boards 130 may connect with one or more external devices 184 to transfer communications through inputs 186. The one or more external devices 184 may be a networking device or other suitable device which can communicate with the network switch 170, and may be connected with the network 188. The inputs 186 between the external devices 184 and the layered circuit boards 130 may be a signal or format able to communicate with the network switch 170 over the network cable sets 182. The layered circuit boards 130 and/or the composite routing cartridge 140 may affixed or secured to the network switch 170, such as before or after the network cable sets 182 are connected with the network switch 170.

In an embodiment, the network cable sets 182 may be connected to the layered circuit boards 130 before being routed through the composite routing cartridge 140. In an embodiment, the network cable sets 182 may be connected to the layered circuit boards 130 and routed through the composite routing cartridge 140 before being provided to the server tray 160 and/or connected to the network switch 170. As illustrated, the composite routing cartridge 140 may change the groupings and/or the orientations of the network cable sets 182 from one end to the other. In an embodiment, the groupings and/or the orientation changes may provide the ends of the network cable sets 182 close to the required internal ports 136 and switch ports 174. The composite routing cartridge 140 may have structural resilience to maintain the routing of the network cable sets 182, such as being composed of reinforced plastic. In an embodiment, the system 180 may be air-cooled or liquid-cooled using one or more liquid cooling devices 162. The liquid cooling devices 162 may provide cooling to at least a portion of the layered circuit boards 130 and at least a portion of the network switch 170. The composite routing cartridge 140 may include airflow openings 142, separate from the network cable sets 182 and on planes parallel to those of the layers, to allow airflow to pass through the composite routing cartridge 140, such as between the layered circuit boards 130 and the network switch 170. The airflow openings 142 may be sized differently to allow for more or less airflow. At least a portion of one or more of the liquid cooling devices 162 may be positioned adjacent to the composite routing cartridge 140, such as passing by the ends of the composite routing cartridge 140 near the network cable sets 182 or through the airflow openings 142, to pass cooling liquid between the layered circuit boards 130 and the network switch 170. In another embodiment, the liquid cooling devices 162 may only provide cooling to a front section or a back section, or both separately, and not pass through or by the composite routing cartridge 140.

FIG. 1C illustrates a top view of an example system 190 for routing network cable, according to at least one embodiment. The system 190 includes network cable sets 182 connected to layered circuit boards 130, routed through composite routing cartridge 140, and connected to network switch 170. In an embodiment, the network cable sets 182 may be connected to the layered circuit boards 130 before being routed through the composite routing cartridge 140. In an embodiment, the network cable sets 182 may be connected to the layered circuit boards 130 and routed through the composite routing cartridge 140 before being provided to the server tray 160 and/or connected to the network switch 170. As illustrated, the composite routing cartridge 140 may change the groupings and/or the orientations of the network cable sets 182 from one end to the other. In an embodiment, the groupings and/or the orientation changes may provide the ends of the network cable sets 182 close to the layered circuit boards 130 and the network switch 170.

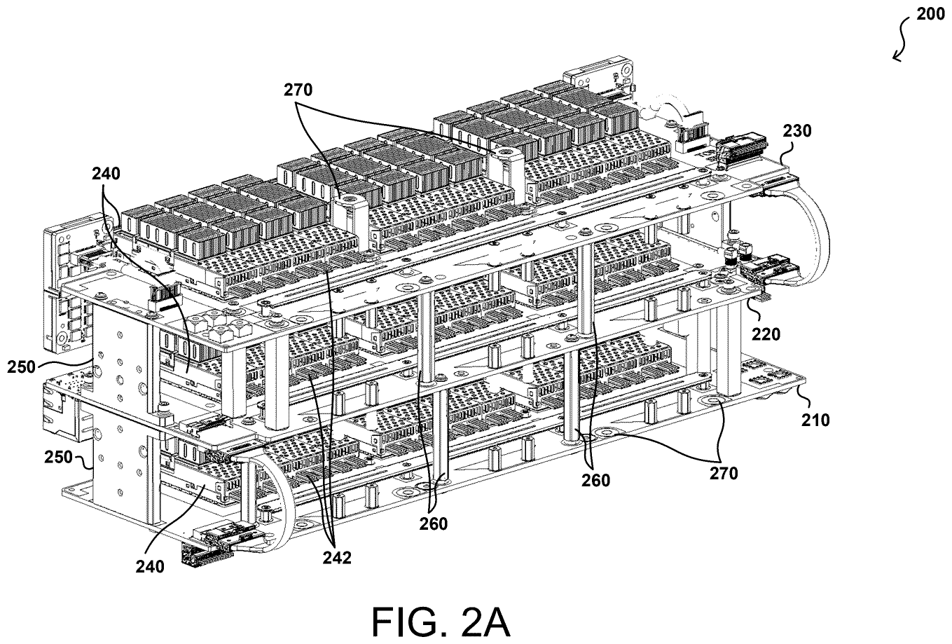

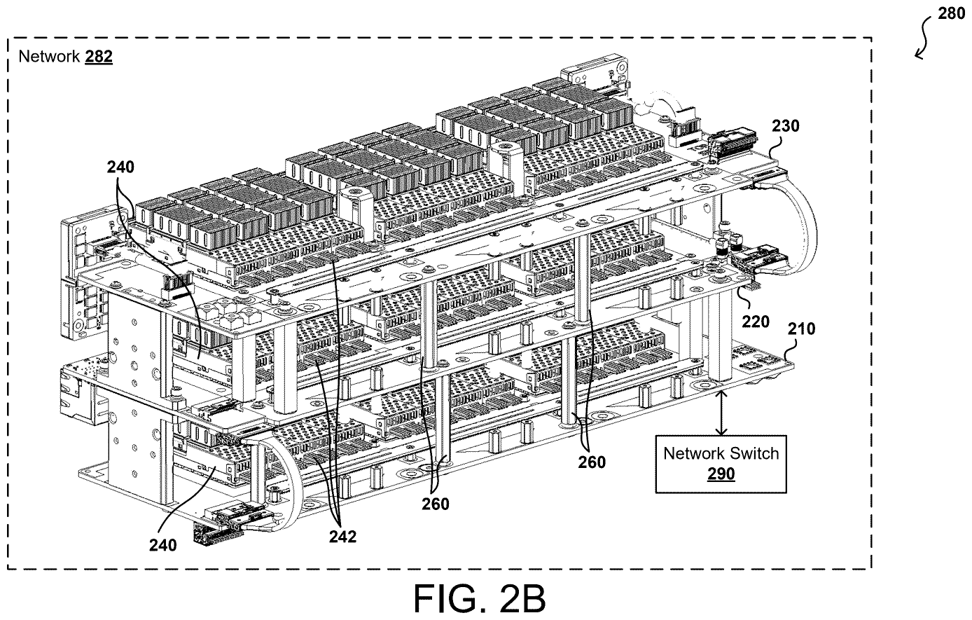

FIG. 2A illustrates a perspective view of an example architecture of a transceiver panel structure 200 for routing network cable, according to at least one embodiment. The architecture of the layered transceiver panel structure 200 may be used with the example systems 100 and 180 illustrated in FIGS. 1A and 1B to bridge connections between external devices and network switches of a server assembly. In an embodiment, the transceiver panel structure 200 may include a bottom transceiver panel 210, a middle transceiver panel 220, and a top transceiver panel 230 which may be securely layered or stacked together. In another embodiment, the transceiver panel structure 200 may have one or more transceiver panels, and may be at least partially determined by the number of transceivers 242 to be used or the available dimensions. The transceiver panels 210, 220, 230 may be PCB cards, octal small form factor pluggable (OSFP) panels, or any other suitable devices. The transceiver panels 210, 220, 230 may include one or more transceiver cages 240 including a plurality of transceivers 242 able to connect with network cables to external devices and to network switches. The transceiver panels 210, 220, 230 may also include other ports or communication connections with the other panels or other devices of the server assembly, such as a network switch.

The transceiver panels 210, 220, 230 may be stacked using spacing elements, including structural side walls 250 positioned at sides of the transceiver panels 210, 220, 230 and including structural supports 260 along surfaces of the transceiver panels 210, 220, 230. In an embodiment, the structural side walls 250 may also be structural supports 260. The spacing elements may be used to ensure a specified distance is maintained between the transceiver panels 210, 220, 230, and may also be used to secure and maintain the transceiver panels 210, 220, 230 together, such as to prevent the layered transceiver panel structure 200 from collapsing under due to the weight of the combined transceiver panels 210, 220, 230. The spacing elements, such as the structural side walls 250 and the structural supports 260 may include shapes, sizes, or dimensions suitable to be connected to the transceiver panels. The structural side walls 250 and structural supports 260 may be connected to at least two transceiver panels to secure the transceiver panels together. The transceiver panel structure 200 may be secured to a server assembly or other components, such as a composite routing cartridge, using attachments 270. In an example, the transceiver panel structure 200 may be secured using attachments 270 as well as one or more fasteners (not shown), such as screws, nuts, bolts, or other suitable devices. The transceiver panel structure 200 may be coupled with a composite routing cartridge to route network cables from the transceiver panel structure 200, through the composite routing cartridge, to be positioned and grouped for connections with other devices, such as a network switch.

The transceiver panel structure 200 includes at least one transceiver 242 for sending and receiving signals, for example, data signals. The data signals may be digital or optical signals modulated with data or other suitable signals for carrying data. The transceivers 242 may include a digital data source, a transmitter, a receiver, and processing circuitry that controls the transceivers 242. The digital data source may include suitable hardware and/or software for outputting data in a digital format (e.g., in binary code and/or thermometer code). The digital data output by the digital data source may be retrieved from memory (not illustrated) or generated according to input (e.g., user input). The transmitter includes suitable software and/or hardware for receiving digital data from the digital data source and outputting data signals according to the digital data for transmission over the communication network to a receiver of a device. The receiver of the transceiver panel structure 200 may include suitable hardware and/or software for receiving signals, such as data signals from the communication network. For example, the receiver may include components for receiving optical signals. The transceivers 242 or selected elements of the transceivers 242 may take the form of a pluggable card or controller for the transceiver panel structure 200. For example, the transceivers 242 or selected elements of the transceivers 242 may be implemented on a network interface card (NIC). Although not explicitly shown, it should be appreciated that the transceiver panel structure 200 and devices in combination with the transceiver panel structure 200 and the transceivers 242 may include other processing devices, storage devices, and/or communication interfaces generally associated with computing tasks, such as sending and receiving data.

FIG. 2B illustrates a perspective view of an example system 280 including architecture of a plurality of layered transceiver panel structures for routing network cable, according to at least one embodiment. The system 280 may be used with the example architecture of the layered transceiver panel structure 200 illustrated in FIG. 2A. In an embodiment, system 280 may be a plurality of layered transceiver panel structures, such as including a bottom transceiver panel 210, a middle transceiver panel 220, and a top transceiver panel 230, as part of a network 282. The system 280 may include the plurality of layered transceiver panel structures 210, 220, 230, a network 282, and other devices or components, such as a network switch 290. The plurality of layered transceiver panels 210, 220, 230 may include one or more transceiver cages 240 including a plurality of transceivers 242 able to connect, using network cables, to devices such as external devices or the network switch 290.

The plurality of layered transceiver panels 210, 220, 230 may be stacked using spacing elements, including structural supports 260 along surfaces of the plurality of layered transceiver panels 210, 220, 230. The spacing elements may be used to ensure a specified distance is maintained between the plurality of layered transceiver panels 210, 220, 230. The spacing elements may also be used to secure and maintain the plurality of layered transceiver panels 210, 220, 230 together, such as to prevent them from collapsing under due to the weight of the combined plurality of layered transceiver panels 210, 220, 230.

The plurality of layered transceiver panels 210, 220, 230 may include at least one transceiver 242 for sending and receiving signals, for example, data signals within the network 282, such as to the network switch 290. Although not explicitly shown, it should be appreciated that the plurality of layered transceiver panels 210, 220, 230 and devices in combination with the plurality of layered transceiver panels 210, 220, 230 and the transceivers 242 may include other processing devices, storage devices, and/or communication interfaces generally associated with computing tasks, such as sending and receiving data within the network 282.

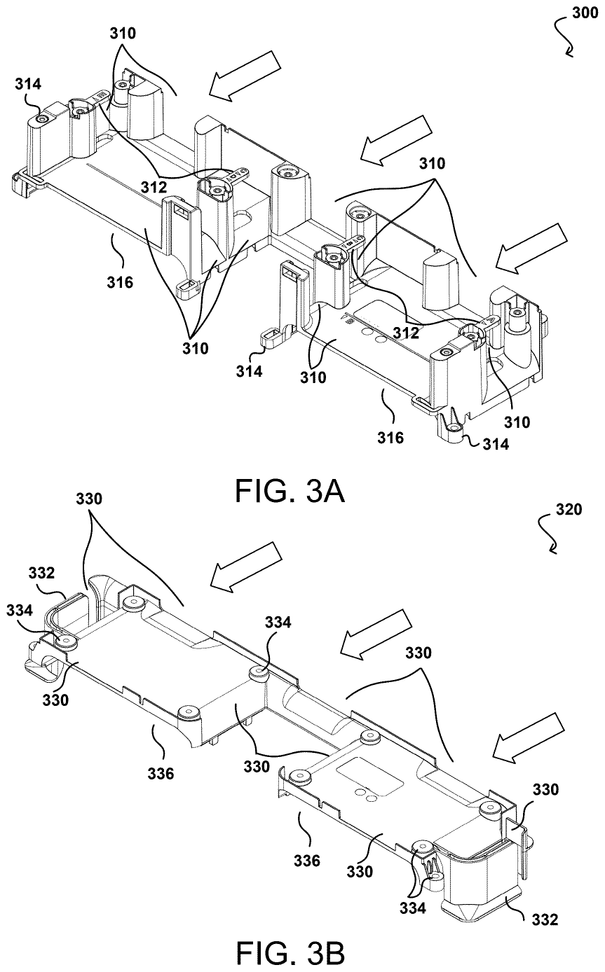

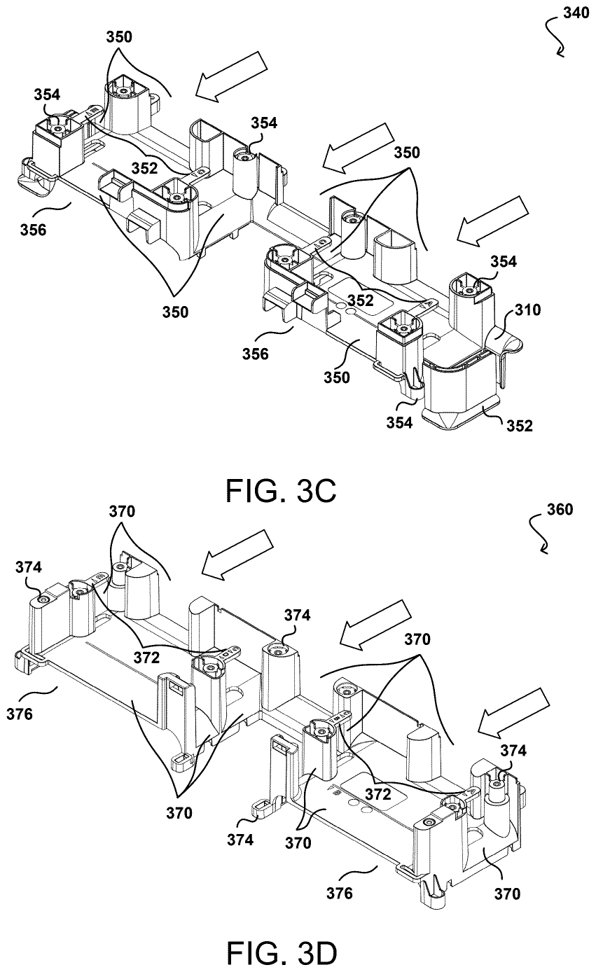

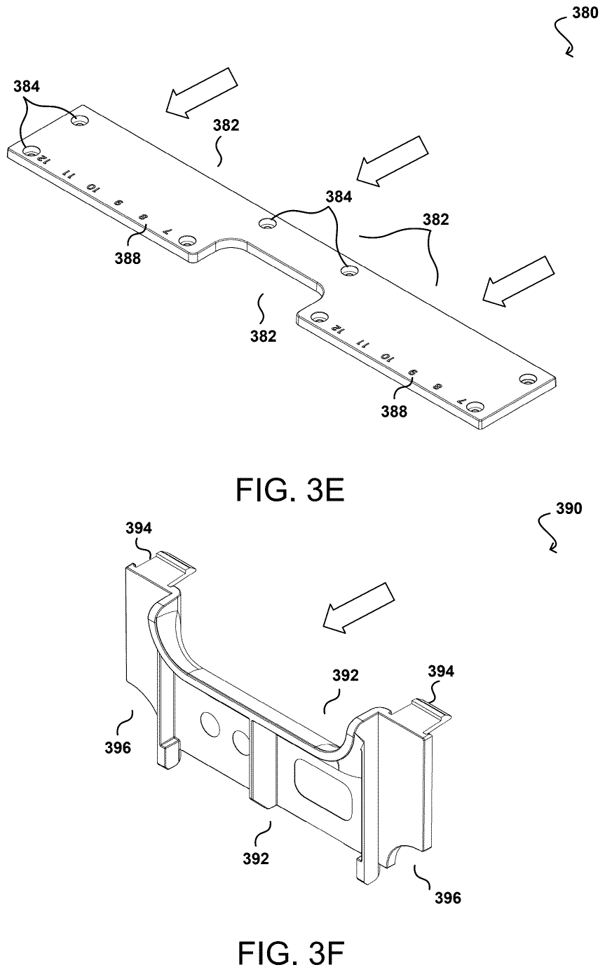

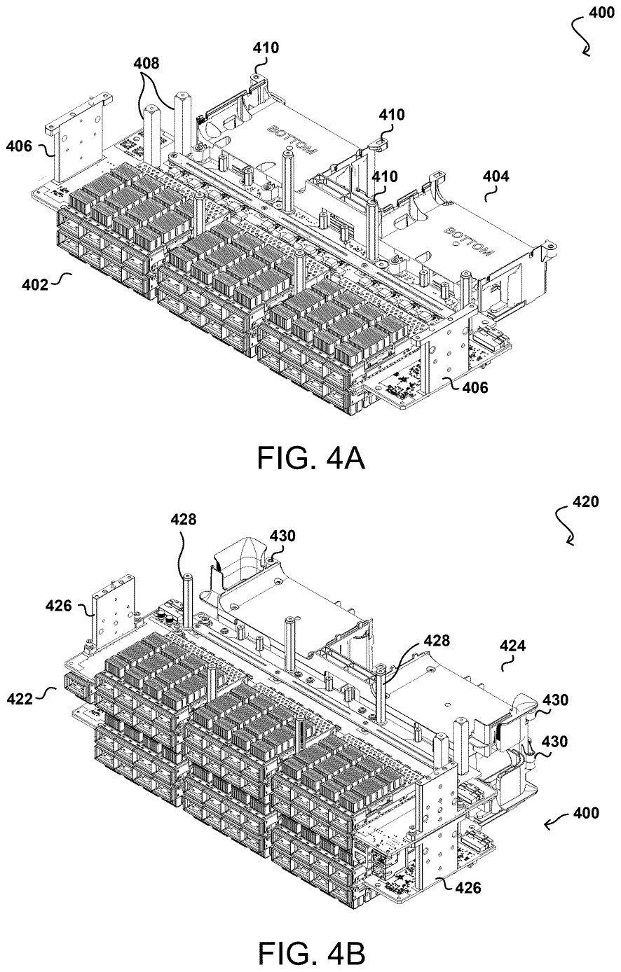

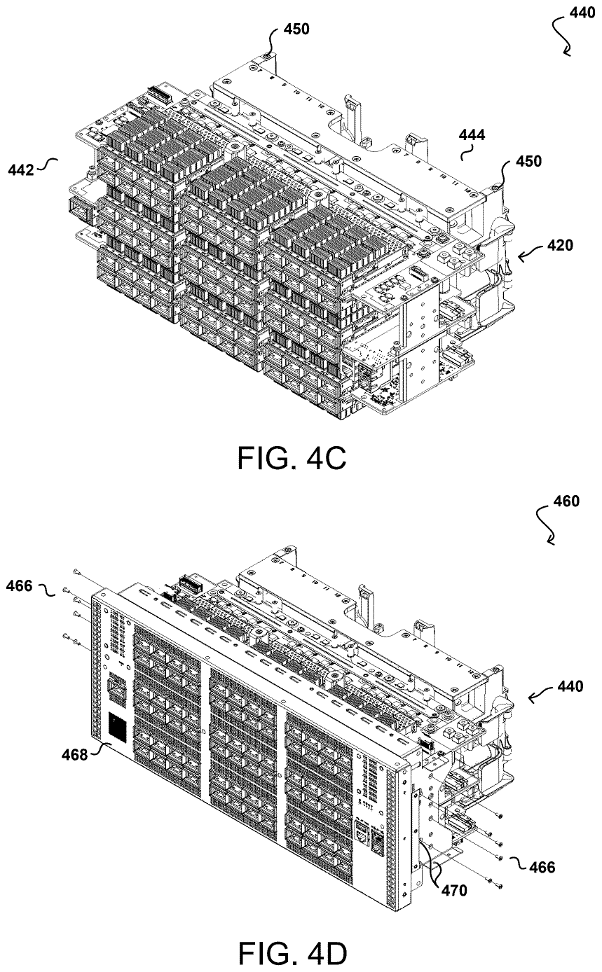

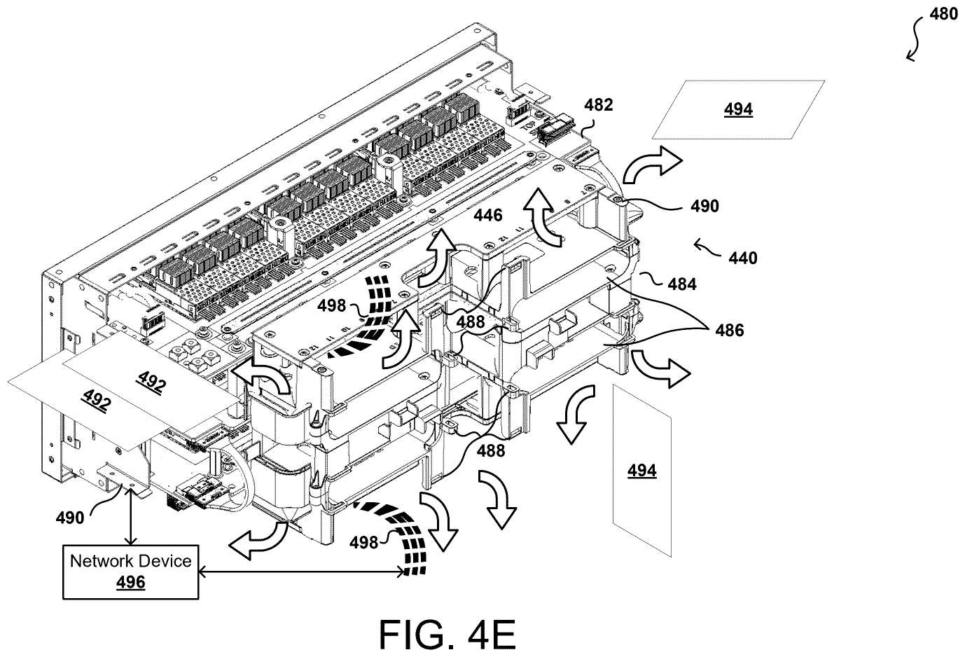

FIG. 3A illustrates an example combinable cable cassette bottom chassis section 300 for routing network cable, according to at least one embodiment. In at least one embodiment, the bottom chassis section 300, with the underside illustrated, may be combined with the combinable cable cassette sections illustrated in FIGS. 3B-3F as a cable cassette assembly, and may include multiple individual combinable cable cassette sections. An example of an at least partially combined cable cassette assembly is illustrated in FIGS. 4A-4E. The combinable cable cassette sections illustrated in FIGS. 3A-3F may be used with the example systems 100 and 180 illustrated in FIGS. 1A and 1B to bridge connections between external devices and network switches of a server assembly. The bottom chassis section 300 may have features, such as surfaces and apertures, to receive network cables on a plane to one or more paths 310 of the bottom chassis section 300 in the directions indicated by the arrows. For example, the network cables may be received from a device of a server assembly, such as a layer of a transceiver panel structure. In another embodiment, the network cables may be received from other directions. The paths 310 may be defined at least in part by the surfaces and the apertures of the bottom chassis section 300, where the paths 310 may be may also used to receive the network cable to the bottom chassis section 300 and provide the network cable from the bottom chassis section 300.

In an embodiment, the paths 310 may be used in any combination to route the network cable, such as to position, orient, reorient, or group the network cable near ports of devices where ends of the cable can be connected. In an embodiment, the network cable may be retained along the paths 310 using features of the bottom chassis section 300, such as projections 312. The projections 312 may extend from a surface of the bottom chassis section 300 and into or over an aperture of the bottom chassis section 300, to retain the network cable within one of the paths 310. In an embodiment, the bottom chassis section 300 may include one or more attachments 314 used to connect the bottom chassis section 300 with other combinable cable cassette sections or other devices. The bottom chassis section 300 may include one or more airflow openings 316 which can be used to allow airflow, such as from an air-cooling device, through the bottom chassis section 300 or the cable cassette assembly. In an embodiment, the airflow openings 316 may be defined by the bottom chassis section 300 as well as other combinable cable cassette sections. In an embodiment, the airflow openings 316 may be used to allow airflow to pass through the bottom chassis section 300 or the cable cassette assembly separate from the network cables.

FIG. 3B illustrates an example combinable cable cassette middle cover section 320 for routing network cable, according to at least one embodiment. In at least one embodiment, the bottom chassis section 300, with the topside illustrated, may be combined with other combinable cable cassette sections as a cable cassette assembly. For example, the underside of the middle cover section 320 may be attached to the topside of the bottom chassis section 300 illustrated in FIG. 3A. The middle cover section 320 may have features, such as surfaces and apertures, to receive network cables on a plane to one or more paths 330 of the middle cover section 320 in the directions indicated by the arrows. For example, the network cables may be received from a device of a server assembly, such as a layer of a transceiver panel structure. In another embodiment, the network cables may be received from other directions. The paths 330 may be defined at least in part by the surfaces and the apertures of the middle cover section 320, where the paths 330 may also be used to receive the network cable to the middle cover section 320 and provide the network cable from the middle cover section 320.

In an embodiment, the paths 330 may be used in any combination to route the network cable, such as to position, orient, or group the network cable near ports of devices where ends of the network cables can be connected. In an embodiment, the network cable may be retained along the paths 330 using features of the middle cover section 320, such as projections 332. The projections 332 may extend from a surface of the middle cover section 320 and into or over an aperture of the middle cover section 320 to retain the network cable within one of the paths 330. In an embodiment, the middle cover section 320 may include one or more attachments 334 used to connect the middle cover section 320 with other combinable cable cassette sections or other devices. The middle cover section 320 may include one or more airflow openings 336 which can be used to allow airflow, such as from an air-cooling device, through the middle cover section 320 or the cable cassette assembly. In an embodiment, the airflow openings 336 may be defined by the middle cover section 320 as well as other combinable cable cassette sections. In an embodiment, the airflow openings 336 may be used to allow airflow to pass through the middle cover section 320 or the cable cassette assembly separate from the network cables.

FIG. 3C illustrates an example combinable cable cassette middle chassis section 340 for routing network cable, according to at least one embodiment. In at least one embodiment, the middle chassis section 340, with the underside illustrated, may be combined with other combinable cable cassette sections as a cable cassette assembly. For example, the underside of the middle chassis section 340 may be attached to the topside of the middle cover section 320 illustrated in FIG. 3B. The middle chassis section 340 may have features, such as surfaces and apertures, to receive network cables on a plane to one or more paths 350 of the middle chassis section 340 in the directions indicated by the arrows. For example, the network cables may be received from a device of a server assembly, such as a layer of a transceiver panel structure. In another embodiment, the network cables may be received from other directions. The paths 350 may be defined at least in part by the surfaces and the apertures of the middle chassis section 340, where the paths 350 may also be used to receive the network cable to the middle chassis section 340 and provide the network cable from the middle chassis section 340.

In an embodiment, the paths 350 may be used in any combination to route the network cable, such as to position, orient, or group the network cable near ports of devices where ends of the network cables can be connected. In an embodiment, the network cable may be retained along the paths 350 using features of the middle chassis section 340, such as projections 352. The projections 352 may extend from a surface of the middle chassis section 340 and into or over an aperture of the middle chassis section 340 to retain the network cable within one of the paths 350. In an embodiment, the middle chassis section 340 may include one or more attachments 354 used to connect the middle chassis section 340 with other combinable cable cassette sections or other devices. The middle chassis section 340 may include one or more airflow openings 356 which can be used to allow airflow, such as from an air-cooling device, through the middle chassis section 340 or the cable cassette assembly. In an embodiment, the airflow openings 356 may be defined by the middle chassis section 340 as well as other combinable cable cassette sections. In an embodiment, the airflow openings 356 may be used to allow airflow to pass through the middle chassis section 340 or the cable cassette assembly separate from the network cables.

FIG. 3D illustrates an example combinable cable cassette top chassis section 360 for routing network cable, according to at least one embodiment. In at least one embodiment, the top chassis section 360, with the top side illustrated, may be combined with other combinable cable cassette sections as a cable cassette assembly. For example, the underside of the top chassis section 360 may be attached to the topside of the middle chassis section 340 illustrated in FIG. 3C. The top chassis section 360 may have features, such as surfaces and apertures, to receive network cables on a plane to one or more paths 370 of the top chassis section 360 in the directions indicated by the arrows. For example, the network cables may be received from a device of a server assembly, such as a layer of a transceiver panel structure. In another embodiment, the network cables may be received from other directions. The paths 370 may be defined at least in part by the surfaces and the apertures of the top chassis section 360, where the paths 370 may also be used to receive the network cable to the top chassis section 360 and provide the network cable from the top chassis section 360.

In an embodiment, the paths 370 may be used in any combination to route the network cable, such as to position, orient, or group the network cable near ports of devices where ends of the network cables can be connected. In an embodiment, the network cable may be retained along the paths 370 using features of the top chassis section 360, such as projections 372. The projections 372 may extend from a surface of the top chassis section 360 and into or over an aperture of the top chassis section 360 to retain the network cable within one of the paths 370. In an embodiment, the top chassis section 360 may include one or more attachments 374 used to connect the top chassis section 360 with other combinable cable cassette sections or other devices. The top chassis section 360 may include one or more airflow openings 376 which can be used to allow airflow, such as from an air-cooling device, through the top chassis section 360 or the cable cassette assembly. In an embodiment, the airflow openings 376 may be defined by the top chassis section 360 as well as other combinable cable cassette sections. In an embodiment, the airflow openings 376 may be used to allow airflow to pass through the top chassis section 360 or the cable cassette assembly separate from the network cables.

FIG. 3E illustrates an example combinable cable cassette top cover section 380 for routing network cable, according to at least one embodiment. In at least one embodiment, the top cover section 380, with the top side illustrated, may be combined with other combinable cable cassette sections as a cable cassette assembly. For example, the underside of the top cover section 380 may be attached to the topside of the top chassis section 360 illustrated in FIG. 3D. In another embodiment, the underside of the top cover section 380 may be attached to the underside of the bottom chassis section 300 illustrated in FIG. 3A. The top cover section 380 may have features, such as surfaces and apertures, to receive network cables on a plane to one or more paths 382 of the top cover section 380 in the directions indicated by the arrows. For example, the network cables may be received from a device of a server assembly, such as a layer of a transceiver panel structure. In another embodiment, the network cables may be received from other directions. The paths 382 may be defined at least in part by the surfaces and the apertures of the top cover section 380, where the paths 382 may also be used to receive the network cable to the top cover section 380 and provide the network cable from the top cover section 380.

In an embodiment, the paths 382 may be used in any combination to route the network cable, such as to position, orient, or group the network cable near ports of devices where ends of the network cables can be connected. In an embodiment, the network cable may be retained along the paths 382 using features of the top cover section 380, such as a surface of the underside or projections (not shown). In an embodiment, the top cover section 380 may include one or more attachments 384 used to connect the top cover section 380 with other combinable cable cassette sections or other devices. The top cover section 380 may include one or more airflow openings (not shown) which can be used to allow airflow, such as from an air-cooling device, through the top cover section 380 or the cable cassette assembly. In an embodiment, the airflow openings may be defined by the top cover section 380 as well as other combinable cable cassette sections. In an embodiment, the airflow openings may be used to allow airflow to pass through the top cover section 380 or the cable cassette assembly separate from the network cables. The top cover section 380 may also include mapping labels 388 which may be used to map network cables located at the labeled position. Other combinable cable cassette sections may also include mapping labels 388. As shown, the mapping labels 388 may comprise numerals, but may use any other suitable label. The mapping labels 388 may correspond with labels on other devices, such as PCB cards or ports of a transceiver panel, a network switch or network cards of a network switch, or network cables. The mapping labels 388 may also correspond with a mapping system used to associate the mapping labels 388 with network cables, and may also incorporate other identification systems, such as color coding. This system may also be used to determine the paths, origination changes, and grouping changes of the network cables. For example, ends of grouped sections of the routed cables may be color coded to correspond to the specific areas or ports of the network switch with which they are to be connected. These grouped sections may have been routed, organized, and positioned to be at least partially positioned near the corresponding areas or ports using the combinable cable cassette sections and assembly. A user may connect and route the network cables using the mapping labels 388 or other identification systems, including during individual steps of assembling the combinable cable cassette sections.

FIG. 3F illustrates an example combinable cable cassette side cover section 390 for routing network cable, according to at least one embodiment. In at least one embodiment, the side cover section 390, with the outer side illustrated, may be combined with other combinable cable cassette sections as a cable cassette assembly, such as using attachments 488 illustrated in FIG. 4E. For example, the inner side of the side cover section 390 may be attached to the outer side of the bottom chassis section 300, middle cover section 320, middle chassis section 340, and top chassis section 360 illustrated in FIGS. 3A, 3B, 3C, and 3D, respectively. The side cover section 390 may have features, such as surfaces and apertures, to receive network cables on a plane to one or more paths 392 of the side cover section 390 in the directions indicated by the arrows. For example, the network cables may be received from a device of a server assembly, such as a layer of a transceiver panel structure, or from other sections of the cable cassette assembly. In another embodiment, the network cables may be received from other directions. The paths 392 may be defined at least in part by the surfaces and the apertures of the side cover section 390, where the paths 392 may also be used to receive the network cable to the side cover section 390 and provide the network cable from the side cover section 390.

In an embodiment, the paths 392 may be used in any combination to route the network cable, such as to position, orient, or group the network cable near ports of devices where ends of the network cables can be connected. In an embodiment, the network cable may be retained along the paths 392 using features of the side cover section 390, such as a surface of the underside or projections (not shown). In an embodiment, the side cover section 390 may include one or more attachments 394 used to connect the side cover section 390 with other combinable cable cassette sections or other devices. The side cover section 390 may include one or more airflow openings 396 which can be used to allow airflow, such as from an air-cooling device, through the side cover section 390 or the cable cassette assembly. In an embodiment, the airflow openings 396 may be defined by the side cover section 390 as well as other combinable cable cassette sections. In an embodiment, the airflow openings 396 may be used to allow airflow to pass through the side cover section 390 or the cable cassette assembly separate from the network cables.

FIG. 4A illustrates an example network cable routing first assembly 400, according to at least one embodiment. In at least one embodiment, the first assembly 400 may be stacked with other network cable routing assemblies as illustrated in FIGS. 4B-4E to assemble a final network cable routing assembly, and may include network cable routing assemblies. In an example, the network cable routing assemblies in any order, direction, orientation, or other configuration to assemble a final network cable routing assembly. The network cable routing assemblies illustrated in FIGS. 4A-4E may be used with the example systems 100 and 180 illustrated in FIGS. 1A and 1B to bridge connections between external devices and network switches of a server assembly. The first assembly 400 may include a PCB card 402 and a network cable management piece 404. The PCB card 402 and the network cable management piece 404 may be separate devices coupled together to form the first assembly 400. In an embodiment, the PCB card 402 may be any suitable device, such as a panel, which includes transceivers or other ports to connect with network cables. For example, the PCB card 402 may include transceiver cages to transfer communication using connected network cables. The PCB card 402 may include coupling elements, such as side walls 406 and stand off supports 408, to couple with other PCB cards or other devices. In an embodiment, the network cable management piece 404 may be one of a variety of modular pieces combinable to form a network cable management device. In an embodiment, network cables may be positioned into the network cable management piece 404 from the PCB card 402 along at least one plane.

A PCB is used to electrically connect electronic components using conductive pathways, or traces, etched from metal sheets. In many electronic systems, one or more very large-scale integrated circuit (“VLSI”) components is coupled to a host system printed circuit board (“PCB”). Such VLSI components may include, for example, central processing unit (“CPU”) devices and graphics processing unit (“GPU”) devices. The PCB may hold at least one processing circuitry. The processing circuitry may comprise hardware, such as an application specific integrated circuit (ASIC). Other non-limiting examples of the processing circuitry include an Integrated Circuit (IC) chip, a Central Processing Unit (CPU), a Graphics Processing Unit (GPU), a microprocessor, a Field Programmable Gate Array (FPGA), a collection of logic gates or transistors, resistors, capacitors, inductors, diodes, or the like. It should be appreciated that any appropriate type of electrical or optical component or collection of electrical or optical components may be suitable for inclusion in the processing circuitry. Numerous example embodiments will be described below in which a semiconductor package is mounted within a through hole of a PCB. Although PCBs having certain types and form factors appear in the drawings and the discussion, it should be noted that the illustrated and described types and form factors are provided by way of example only. Persons having skill in the art and having reference to this disclosure will readily appreciate that the same or similar apparatus and techniques may also be employed with PCBs having other types and form factors. For example, in some embodiments, the PCB to which the semiconductor package is mounted may comprise an add-in card, such as a PCIe card, that is configured to be coupled to a system board or motherboard of a host system. In other embodiments, the PCB to which the semiconductor package is mounted may be the system board or motherboard of the host system itself. Moreover, the system board or the motherboard may be associated with any type of host system. For example, the PCB may comprise the system board in a multi-node rack-mounted server in a data center, or it may comprise the motherboard of a workstation, desktop, laptop, or mobile device. Other embodiments are also possible.

The network cable management piece 404 along with the other network cable management pieces may be used to change grouping and orientation between one or more planes, such as parallel or perpendicular, for at least a portion of network cable positioned through the variety of modular pieces. At least some of the grouping and orientation changes may be performed when combining the variety of modular pieces. The variety of modular pieces, including the network cable management piece 404, may have features, such as walls, apertures, and projections, to maintain the grouping and orientation changes of the network cables. At least a part of the network cable management piece 404 may be made from reinforced plastic, or other suitable material, to provide sufficient support for maintaining the grouping and orientation changes of the network cables. The network cable management piece 404 may include coupling elements, such as attachments 410, to couple with other network cable management pieces or other devices, such as the PCB card 402 or a network switch connected to the network cables routed through the network cable management piece 404. In an example, the network cable management piece 404 may be secured using attachments 410 as well as one or more fasteners (not shown), such as screws, nuts, bolts, or other suitable devices.

FIG. 4B illustrates an example network cable routing second assembly 420, according to at least one embodiment. In at least one embodiment, a portion of the second assembly 420 may be stacked with other network cable routing assemblies as a final network cable routing assembly. For example, a portion of the second assembly 420 may be stacked on the first assembly 400, as shown, such as after network cables have been received to the first assembly 400. The second assembly 420 may include a PCB card 422 and a network cable management piece 424. The PCB card 422 and the network cable management piece 424 may be separate devices coupled together to form the second assembly 420. In an embodiment, the PCB card 422 may be any suitable device, such as a panel, which includes transceivers or other ports to connect with network cables. For example, the PCB card 422 may include transceiver cages to transfer communication using connected network cables. The PCB card 422 may include coupling elements, such as side walls 426 and stand off supports 428, to couple with other PCB cards or other devices. In an embodiment, the network cable management piece 424 may be one of a variety of modular pieces combinable to form a network cable management device. In an embodiment, network cables may be positioned into the network cable management piece 424 from the PCB card 422 along at least one plane.

The network cable management piece 424 along with the other network cable management pieces may be used to change grouping and orientation between one or more planes for at least a portion of network cables positioned through the variety of modular pieces. At least some of the grouping and orientation changes may be performed when combining the variety of modular pieces. The variety of modular pieces, including the network cable management piece 424, may have features, such as walls, apertures, and projections, to maintain the grouping and orientation changes of the network cables. At least a part of the network cable management piece 424 may be made from reinforced plastic, or other suitable material, to provide sufficient support for maintaining the grouping and orientation changes of the network cables. The network cable management piece 424 may include coupling elements, such as attachments 430, to couple with other network cable management pieces or other devices, such as the PCB card 422 or a network switch connected to the network cables routed through the network cable management piece 424.

FIG. 4C illustrates an example network cable routing third assembly 440, according to at least one embodiment. In at least one embodiment, a portion of the third assembly 440 may be stacked with other network cable routing assemblies as a final network cable routing assembly. For example, a portion of the third assembly 440 may be stacked on the second assembly 420, as shown, such as after network cables have been received to the second assembly 420. The third assembly 440 may include a PCB card 442 and a network cable management piece 444. The PCB card 442 and the network cable management piece 444 may be separate devices coupled together to form the assembly 440. In an embodiment, the PCB card 442 may be any suitable device, such as a panel, which includes transceivers or other ports to connect with network cables. For example, the PCB card 442 may include transceiver cages to transfer communication using connected network cables. The PCB card 442 may include coupling elements (not shown) to couple with other PCB cards or other devices. In an embodiment, the network cable management piece 444 may be one of a variety of modular pieces combinable to form a network cable management device. In an embodiment, network cables may be positioned into the network cable management piece 444 from the PCB card 442 along at least one plane.

The network cable management piece 444 along with the other network cable management pieces may be used to change grouping and orientation between one or more planes for at least a portion of network cables positioned through the variety of modular pieces. At least some of the grouping and orientation changes may be performed when combining the variety of modular pieces. The variety of modular pieces, including the network cable management piece 444, may have features, such as walls, apertures, and projections, to maintain the grouping and orientation changes of the network cables. At least a part of the network cable management piece 444 may be made from reinforced plastic, or other suitable material, to provide sufficient support for maintaining the grouping and orientation changes of the network cables. The network cable management piece 444 may include coupling elements, such as attachments 450, to couple with other network cable management pieces or other devices, such as the PCB card 442 or a network switch connected to the network cables routed through the network cable management piece 444.

FIG. 4D illustrates a front view of an example network cable routing fourth assembly 460, according to at least one embodiment. In at least one embodiment, a portion of the fourth assembly 460 may be combined with other network cable routing assemblies as a final network cable routing assembly. For example, a portion of the fourth assembly 460 may be combined with the third assembly 440, as shown, such as after network cables have been received to the third assembly 440. The fourth assembly 460 may include a front panel 468 attachable at the front of fourth assembly 460. The front panel 468 may be attached to the third assembly 440 or other devices, such as a server tray, using fasteners 466 and attachments 470. The fourth assembly 460 may be provided as a final network cables routing assembly. The fourth assembly 460 may be provided to a network switch, or to a server tray including a network switch, to connect the network cables from one or more PCB cards and routed through a variety of modular pieces of a network cable management device. In an example, the fourth assembly 460 may include eighteen 1×4 (OSFP) cages on three separate parallel planes and one 1×1 OSFP cage to be connected by OSFP cables, and may have at least 72 OSFP cable harnesses. The OSFP cables may then need to be connected to four different ASICs on two separate parallel planes within a about 4 rack unit height and about 19 inches wide server tray while allowing sufficient air flow to pass through the fourth assembly 460 to cool devices within the server tray. Each 1×4 OSFP cage and the 1×1 OSFP cage may have 4 NCI connectors which connect with a harness creating a total of 76 high speed NCI connectors that can connect to the 4 ASICs of a network switch. Therefore, the final network cable routing assembly may include an architecture of a OSFP panel structure.

The switches or network switches may be 1U switches, where “1U” refers to the industry-standard size for rack-mounted switches and servers. The switches may be electrical switches, optical switches, hybrid electro-optical switches, or any combination thereof. The switches may be implemented with suitable hardware and/or software that enables the routing of signals in the appropriate domain. For example, an electrical switch may include receivers that receive and convert optical signals into electrical signals for routing within the electrical switch. A receiver of an electrical switch may include a transimpedance amplifier (TIA), a photodetector, and a controller which all serve to convert the optical signals into electrical signals. Each electrical switch may further include transmitters that convert electrical signals routed within the electrical switch into optical signals for output to another switch (optical or electrical) within the system. For example, a transmitter of an electrical switch may include a light source, a modulator, and a controller that controls the modulator and light source. In some embodiments, receiver/transmitter pairs may be integrated into a single transceiver. Each electrical switch may also include internal switching circuitry for routing electrical signals within the electrical switch.

Throughout the instant description, the terms “electrical switch,” “electrical switching ASIC,” “ASIC,” and variants thereof are used interchangeably. Although FIGS. 1A and 1B illustrate the electrical switches in the electrical blocks as being embodied by ASICs, example embodiments are not limited thereto, and the electrical switches may be implemented with any suitable hardware and/or software that enables routing of signals in the electrical domain. In addition, a set of optical switches at one or more levels of a hybrid optoelectrical switch may be referred to herein as an optical block while a set of electrical switches at one or more levels of a hybrid optoelectrical switch may be referred to as an electrical block.

For example, an electrical switch may include receivers that receive and convert optical signals into electrical signals for routing within the electrical switch. For example, a receiver of an electrical switch may include a transimpedance amplifier (TIA), a photodetector, and a controller which all serve to convert the optical signals into electrical signals. Each electrical switch may further include transmitters that convert electrical signals routed within the electrical switch into optical signals for output to another switch (optical or electrical) within the system. For example, a transmitter of an electrical switch may include a light source, a modulator, and a controller that controls the modulator and light source. In at least one example embodiment, receiver/transmitter pairs are integrated into a single transceiver. Each electrical switch may further include internal switching circuitry for routing electrical signals within the electrical switch.

Optical switches are one solution for enabling advances in networking due to the technology's potential for very high data capacity and low power consumption. Optical switches feature optical input and output ports and are capable of routing light that is coupled to the input ports to the intended output ports on demand, according to one or more control signals (electrical or optical control signals). Routing of the signals is performed in the optical domain, i.e. without the need for optical-electrical and electrical-optical conversion, thus bypassing the need for power-consuming transceivers. Header processing and buffering of the data is not possible in the optical domain and thus, packet switching (as it is realized in electrical switches) cannot be employed. Instead, the circuit switching paradigm is used: an end-to-end circuit is created for the communication between two endpoints connected on the input and the output of the optical switch. Director switches may be used in the most common data center interconnection topologies, e.g., fat trees, Slim Fly, and Dragonfly+). In addition, inventive concepts propose to place such hybrid switching systems “in the middle” of the network (e.g., replacing the edge/top of rack (TOR) layer and aggregation layer).

An optical switch may include hardware and/or software for routing signals in the optical domain. Thus, in one embodiment, an optical switch may include input optical fibers and output optical fibers that carry optical signals as well as one or more devices suited for routing optical signals within the optical switch. For example, the one or more devices for routing optical signals may include one or more movable mirrors (e.g., MEMS mirrors) that are controlled to move in a manner that directs light from an input fiber to a desired output fiber or to move in a manner that forces or guides light from one waveguide into another waveguide. An optical switch may include one or more devices for amplifying light in order to compensate for propagation and scattering losses introduced by the optical switch. In at least one example embodiment, signals input and output to an ASIC are optical, meaning that each optical switch connected to an electrical switch routes optical signals received from the electrical switch without using hardware and/or software that converts an electrical signal into an optical signal for routing within the optical switch. However, example embodiments are not limited thereto, and an optical switch may include electrical to optical to electrical conversion hardware and/or software if desired (e.g., if the input signal and/or output signal is an electrical signal).

The optical switch(es) may include an arrayed waveguide grating router (AWGR), which is a passive switch fabric. In some embodiments, the optical switch(es) may correspond to a passive element that operates as a wavelength router that uses multiple wavelengths to interconnect outputs and inputs by following a specific cyclic wavelength routing pattern.

An optical switch, on the other hand, may function by directly routing optical signals without converting them to electrical signals. Each optical switch may include optical receivers, such as photodetectors and wavelength-division multiplexing (WDM) demultiplexers, that receive incoming optical signals. These optical signals may then be directed through internal optical switching components, such as micro-electromechanical systems (MEMS) mirrors, waveguides, or optical cross-connects, which route the signals to the appropriate output paths. The optical switch may also include optical transmitters, such as laser diodes and modulators, which transmit the routed optical signals to the next switch in the network. A hybrid electro-optical switch may combine both electrical and optical components to route signals. Such a switch may include receivers that convert optical signals into electrical signals using TIAs and photodetectors, similar to those in electrical switches. These electrical signals can then be routed within the switch using internal electrical switching circuitry. Additionally, the hybrid switch may contain optical switching components, such as WDM multiplexers and MEMS devices, to route optical signals directly. The transmitters in a hybrid switch may include both electrical-to-optical converters and direct optical transmitters, enabling the hybrid switch to interface with both electrical and optical networks. For example, a hybrid switch's transmitter may include a light source, a modulator for optical signals, and traditional electrical signal transmitters, providing routing capabilities across different signal domains.

The interconnections between the switches within the network topology may be implemented via optical fibers or traditional electrical cables, depending on the specific requirements of the system. For instance, the communication lanes may be constructed of dedicated differential cable pairs and/or fiber optics, each tailored to provide optimal performance for the data transmission needs. The dedicated differential cable pairs used in these interconnections may include a variety of cable media such as copper, aluminum, gold, silver, nickel, or composite materials like copper-clad aluminum, copper-clad steel, or bimetallic conductors. These materials may be chosen for their electrical conductivity and durability, ensuring reliable and efficient data transmission. For example, in a four-lane network, each lane may consist of its own dedicated copper cable, providing isolated physical paths for each communication lane of a deserialized data stream. This configuration helps in maintaining signal integrity and reducing crosstalk between lanes.

Alternatively, fiber optic cables may be employed for the interconnections. Fiber optics are capable of transmitting data streams via different wavelengths of light, with each data stream assigned a unique wavelength. The use of fiber optic cables may allow multiple data streams to be transmitted simultaneously through a single fiber optic cable, significantly increasing the bandwidth and efficiency of the network, and particularly advantageous for long-distance data transmission and for applications requiring high data transfer rates. Various optical networking technologies can be used to transmit multiple optical signals (e.g., data signals or data streams) over a single optical fiber within an optical link with little to no optical signal interference. These technologies may be used to improve bandwidth efficiency and reduce the amount of infrastructure needed for data communication.

One such technology is Time Division Multiplexing (TDM). In TDM, multiple optical signals can be transmitted over a single optical fiber by assigning each optical signal a respective time slot and transmitting an optical signal during its assigned time slot. The time slots are allocated in a cyclic manner, with each optical signal transmitting a small amount of data during its assigned time slot. The time slots are very short, on the order of microseconds, and the cycle repeats many times per second, allowing for rapid data transfer.

Another technology is Frequency Division Multiplexing (FDM). In FDM, multiple optical signals can be transmitted over a single optical fiber by assigning each optical signal a respective frequency band. Each optical signal is modulated onto a respective carrier frequency to generate a modulated signal, and these modulated signals are combined and transmitted over a single optical fiber. At the receiver, the modulated signals are separated using filters (e.g., band-pass filters) that permit optical signals meeting specific frequency specifications to pass through while filtering out other signals. FDM allows optical links to simultaneously transmit multiple channels over the same frequency band.

Yet another technology is Wavelength Division Multiplexing (WDM). In WDM, multiple optical signals having different wavelengths are combined into a single optical signal and transmitted over a single optical fiber. WDM techniques involve combining and separating multiple optical signals with different wavelengths onto a single optical fiber, allowing for more data to be transmitted and increasing the capacity of the optical fiber.

Examples of WDM technology include Coarse Wavelength Division Multiplexing (CWDM) and Dense Wavelength Division Multiplexing (DWDM). CWDM combines multiple optical signals at different wavelengths into a single optical signal and transmits it over a single optical fiber. CWDM uses a wider wavelength separation, such as about 80 nanometers (nm), which means it supports fewer channels and has lower power budgets, making it suitable for shorter distances, up to about 80 kilometers (km). CWDM requires less complex equipment and lower-cost optical components, making it a cost-effective solution for applications that do not require dense wavelength separation. In contrast, DWDM uses narrower wavelength separation, such as about 0.8 nm, allowing for higher channel capacity and longer distances, but typically at a higher cost and complexity.

In an embodiment, a switch may comprise input circuits and output circuits, linked by switching core. The switch may be in a network, most specifically in a switching fabric, such as an InfiniBand fabric. Thus, the switch may comprise multiple inputs and outputs, like the network switch 170 shown in FIG. 1A.

A number of architectures of this type have been proposed, including “Next Generation I/O” (NGIO) and “Future I/O” (FIO), culminating in the “InfiniBand” architecture, which has been advanced by a consortium led by a group of industry leaders (including Intel, Sun, Hewlett Packard, IBM, Compaq, Dell and Microsoft). Storage Area Networks (SAN) provide a similar, packetized, serial approach to high-speed storage access, which can also be implemented using an InfiniBand fabric.

Communications between a parallel bus and a packet network generally require a communications interface, to convert bus cycles into appropriate packets and vice versa. For example, a host channel adapter or target channel adapter can be used to link a parallel bus, such as the PCI bus, to the InfiniBand fabric. When the adapter receives data from a device on the PCI bus, it inserts the data in the payload of an InfiniBand packet, and then adds an appropriate header and error checking code, such as a cyclic redundancy check (CRC) code, as required for network transmission. The InfiniBand packet header includes a routing header and a transport header. The routing header contains information at the data link protocol level, including fields required for routing the packet within and between fabric subnets. The transport header contains higher-level, end-to-end transport protocol information. Similar headers are used in other types of packet networks known in the art, such as Internet Protocol (IP) networks.

In at least one embodiment, a computer system may be used in other devices such as handheld devices and embedded applications. Some examples of handheld devices include cellular phones, Internet Protocol devices, digital cameras, personal digital assistants (“PDAs”), and handheld PCs. In at least one embodiment, embedded applications may include a microcontroller, a digital signal processor (DSP), an SoC, network computers (“NetPCs”), set-top boxes, network hubs, wide area network (“WAN”) switches, or any other system that may perform one or more instructions. In an embodiment, computer system may be used in devices such as graphics processing units (GPUs), network adapters, central processing units, and network devices such as switches (e.g., a high-speed direct GPU-to-GPU interconnect such as the NVIDIA GH100 NVLINK or the NVIDIA Quantum 2 64 Ports InfiniBand NDR Switch).

Optical cables and connectors may be designed to comply with any applicable standard, for example Ethernet and InfiniBand standards, such as Ethernet variants 200GBASE-FR4, 400GBASE-FR4, and 100GBASE-LR4 to support four wavelengths.

FIG. 4E illustrates a rear view of an example network cable routing fifth assembly of a variety of modular pieces 480, similar to the fourth assembly 460 illustrated in FIG. 4D according to at least one embodiment. In at least one embodiment, a portion of the variety of modular pieces 480 may be combined with other network cable routing assemblies as a final network cable routing assembly. For example, a portion of the variety of modular pieces 480 may be combined with the third assembly 440, as shown, such as after network cables, such as cables positioned in harnesses 498, have been received to the third assembly 440. The variety of modular pieces 480 may be provided as a final network cable routing assembly. The variety of modular pieces 480 may be provided to one or more network devices 496, such as a network switch, or to a server tray including a network switch, to connect the network cables from one or more PCB cards 482 along parallel planes 492 and routed through a variety of modular pieces of a network cable management device 484.

The variety of modular pieces 480 may be used to position at least a portion of network cables, such as cables positioned in the harnesses 498, on planes 494 perpendicular to the parallel planes 492 of the PCB cards 482 and the network cable management device 484 layers, in the directions indicated by the arrows. The harnesses 498 may be positioned in the perpendicular planes 494 using the variety of modular pieces of the network cable management device 484. For example, the side cover 390 illustrated in FIG. 3F may be attached to the network cable management device 484 at attachments 488 to maintain the harnesses in the perpendicular planes 494. At least some of the grouping and orientation changes of the network cables or the harnesses 498 from the parallel planes 492 to the perpendicular planes 494 may be performed when combining the variety of modular pieces. In an embodiment, an additional modular piece 446, such as part of third assembly 440, may be combined with network cable management device 484 to maintain at least one grouping or orientation change of the network cables or the harnesses 498. The harnesses 498 may be positioned using the network cable management device 484 to change grouping or orientation of the harnesses 498, such as to direct the ends of the harnesses 498 near required network connections with a network device 496, such as a network switch. The network cable management device 484 may include coupling elements, such as attachments 490 used to couple or affix the network cable management device 484 with other devices, such as the network devices 496 which can also have a network connection using the harnesses 498. In an example, the network cable management device 484 may be secured to a network device 496 using attachments 490 as well as one or more fasteners (not shown), such as screws, nuts, bolts, or other suitable devices. The network cable management device 484 may include airflow openings 486 to allow airflow, such as for air cooling, to pass through the network cable management device 484, separate from the harnesses 498. The airflow opening 486 may be formed by the variety of modular pieces of a network cable management device 484.

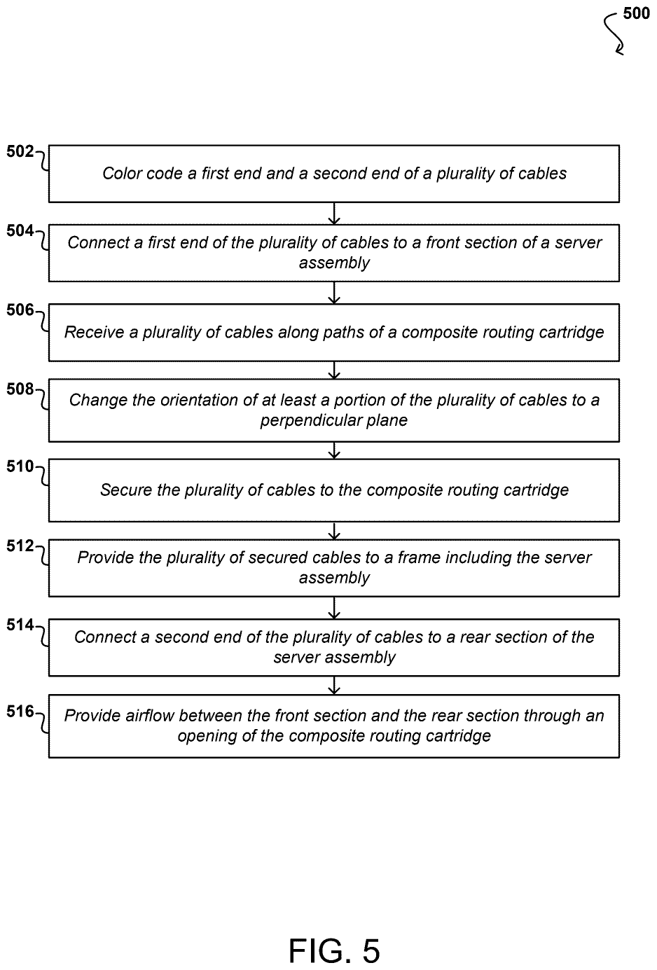

FIG. 5 illustrates an example process 500 that can be used to route a plurality of cables in a server assembly, according to at least one embodiment. It should be understood that for this and other processes presented herein that there may be additional, fewer, or alternative operations performed in similar or alternative orders, or at least partially in parallel, within the scope of the various embodiments unless otherwise specifically stated. In this example, a first end and a second end of a plurality of cables may be color coded 502. One or more portions of the plurality of cables may have different colors of the color code, such as to indicate separate grouping or to correspond with connections to be made. The color code may be used to indicate different connections to be made for the first end and a second end of a plurality of cables, such first area or port for the first end and a second area or port for the second end. In at least one embodiment, a first end of a plurality of cables may be connected 504 to a front section of a server assembly. The front section of the server assembly may include one or more stackable PCB cards. A portion of the plurality of cables may not be connected to the front section of a server assembly. The front section of the server assembly may include ports facing toward a rear section of the server assembly to receive the first end of plurality of cables. In at least one embodiment, a plurality of cables may be received 506 along paths of a composite routing cartridge. The plurality of cables may have opposing ends extending out from the composite routing cartridge. For example, one end may extend toward the front section and the other end may extend toward the rear section. The composite routing cartridge may be composed at least partially of reinforced plastic. The paths of a composite routing cartridge may change the grouping of the plurality of cables as the cartridge is assembled.

In at least one embodiment, the orientation of at least a portion of the plurality of cables may be changed 508 to a perpendicular plane. The at least portion of the paths of the composite routing cartridge may be on a first plane, and portions of the plurality of cables may be changed to another orientation using the composite routing cartridge, such as to align with sections of the server assembly. The different orientations of the plurality of cables in the composite routing cartridge may be made as the cartridge is assembled. In at least one embodiment, the plurality of cables may be secured 510 to the composite routing cartridge. The composite routing cartridge may have a modular section, including modular sections to retain at least portions of the plurality of cables. The composite routing cartridge may have retaining features shaped and positioned to retain at least portions of the plurality of cables. In at least one embodiment, the plurality of secured cables may be provided 512 to a frame including the server assembly. The rear section of the server assembly may be positioned in the frame before the plurality of secured cables are provided. The secured cables may be connected to the front section of the server assembly before the plurality of secured cables are provided. The frame assembly may include features to secure the front section, the composite routing cartridge, and/or the rear section.

In at least one embodiment, a second end of the plurality of cables may be connected 514 to the rear section of the server assembly. The rear section, or devices on the rear section, may have features, such as ports, to receive the second end of the plurality of cables. The features of the rear section may be at least partially positioned with the locations of the second end of the plurality of cables. The rear section of the server assembly may include one or more ASICs. A portion of the plurality of cables may not be connected to the rear section of a server assembly. The rear section of the server assembly may include ports facing toward the front section of the server assembly to receive the second end of plurality of cables. In at least one embodiment, airflow between the front section and the rear section may be provided 516 through an opening of the composite routing cartridge. Devices may provide air cooling and/or liquid cooling to the server assembly, such as to a front section and a back section, passing through the composite routing cartridge. The opening of the composite routing cartridge may be separate from areas of the composite routing cartridge that contain the plurality of network cables.

In an example, a method of assembly may be used which includes assembling each layer of OSFP and pre-wiring the braids on the card plane, such as right and left. Then the method can include assembling the three PCB cards that have undergone initial wiring, each in its own plane. Then the method can include wiring the braids in a plane perpendicular to the plane of cards, such as up and down. Finally, the method can include assembling the three-layer assembly of PCB cards with all connectors, braids, and wiring braids, and then connecting them to ASICs, such as forward and backward.

As discussed, aspects of various approaches presented herein can be lightweight enough to execute on a device such as a client device, such as a personal computer or gaming console, in real time. Such processing can be performed on, or for, content that is generated on, or received by, that client device or received from an external source, such as streaming data or other content received over at least one network. In some instances, the processing and/or determination of this content may be performed by one of these other devices, systems, or entities, then provided to the client device (or another such recipient) for presentation or another such use.

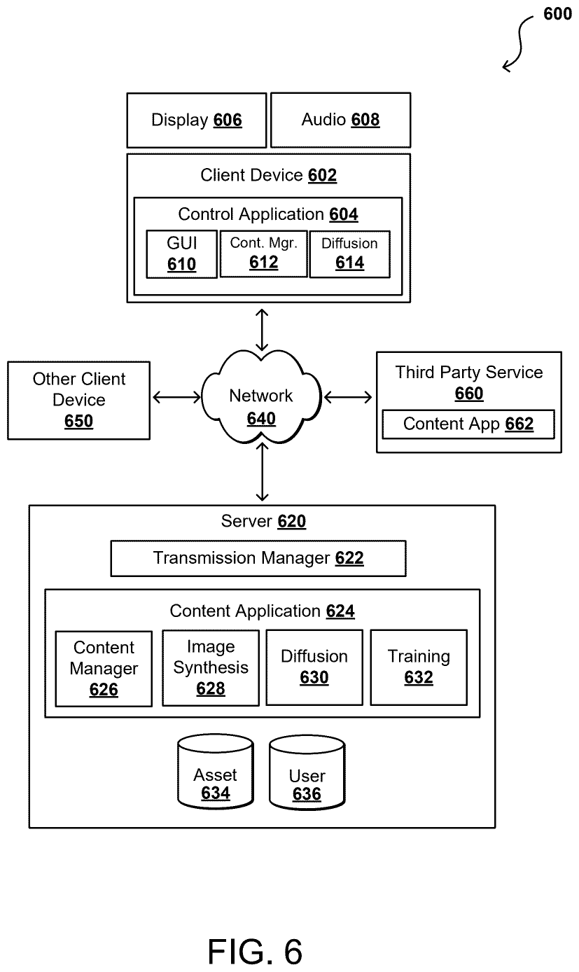

As an example, FIG. 6 illustrates an example network configuration 600 that can be used to provide, generate, modify, encode, process, and/or transmit image data or other such content. In at least one embodiment, a client device 602 can generate or receive data for a session using components of a control application 604 on client device 602 and data stored locally on that client device. In at least one embodiment, a content application 624 executing on a server 620 (e.g., a cloud server or edge server) may initiate a session associated with at least one client device 602, as may utilize a session manager and user data stored in a user database 636, and can cause content such as one or more digital assets (e.g., object representations) from an asset repository 634 to be determined by a content manager 626. A content manager 626 may work with an image synthesis module 628 to generate or synthesize new objects, digital assets, or other such content to be provided for presentation via the client device 602. In at least one embodiment, this image synthesis module 628 can use one or more neural networks, or machine learning models, which can be trained or updated using a training module 632 or system that is on, or in communication with, the server 620. This can include training and/or using a diffusion model 630 to generate content tiles that can be used by an image synthesis module 628, for example, to apply a non-repeating texture to a region of an environment for which image or video data is to be presented via a client device 602. At least a portion of the generated content may be transmitted to the client device 602 using an appropriate transmission manager 622 to send by download, streaming, or another such transmission channel. An encoder may be used to encode and/or compress at least some of this data before transmitting to the client device 602. In at least one embodiment, the client device 602 receiving such content can provide this content to a corresponding control application 604, which may also or alternatively include a graphical user interface 610, content manager 612, and image synthesis or diffusion module 614 for use in providing, synthesizing, modifying, or using content for presentation (or other purposes) on or by the client device 602. A decoder may also be used to decode data received over the network 640 for presentation via client device 602, such as image or video content through a display 606 and audio, such as sounds and music, through at least one audio playback device 608, such as speakers or headphones. In at least one embodiment, at least some of this content may already be stored on, rendered on, or accessible to client device 602 such that transmission over network 640 is not required for at least that portion of content, such as where that content may have been previously downloaded or stored locally on a hard drive or optical disk. In at least one embodiment, a transmission mechanism such as data streaming can be used to transfer this content from server 620, or user database 636, to client device 602. In at least one embodiment, at least a portion of this content can be obtained, enhanced, and/or streamed from another source, such as a third party service 660 or other client device 650, that may also include a content application 662 for generating, enhancing, or providing content. In at least one embodiment, portions of this functionality can be performed using multiple computing devices, or multiple processors within one or more computing devices, such as may include a combination of CPUs and GPUs.

In this example, these client devices can include any appropriate computing devices, as may include a desktop computer, notebook computer, set-top box, streaming device, gaming console, smartphone, tablet computer, VR headset, AR goggles, wearable computer, or a smart television. Each client device can submit a request across at least one wired or wireless network, as may include the Internet, an Ethernet, a local area network (LAN), or a cellular network, among other such options. In this example, these requests can be submitted to an address associated with a cloud provider, who may operate or control one or more electronic resources in a cloud provider environment, such as may include a data center or server farm. In at least one embodiment, the request may be received or processed by at least one edge server, that sits on a network edge and is outside at least one security layer associated with the cloud provider environment. In this way, latency can be reduced by enabling the client devices to interact with servers that are in closer proximity, while also improving security of resources in the cloud provider environment.

### Data Center

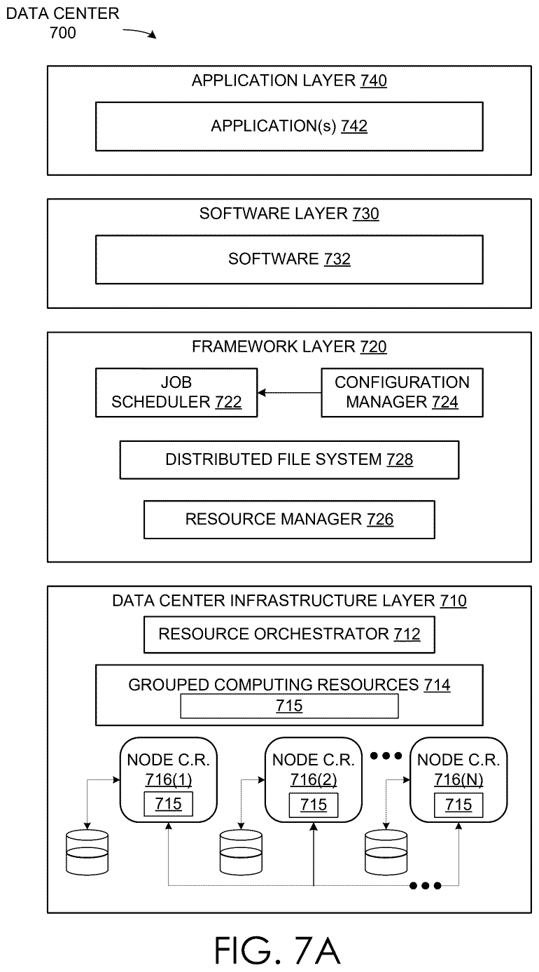

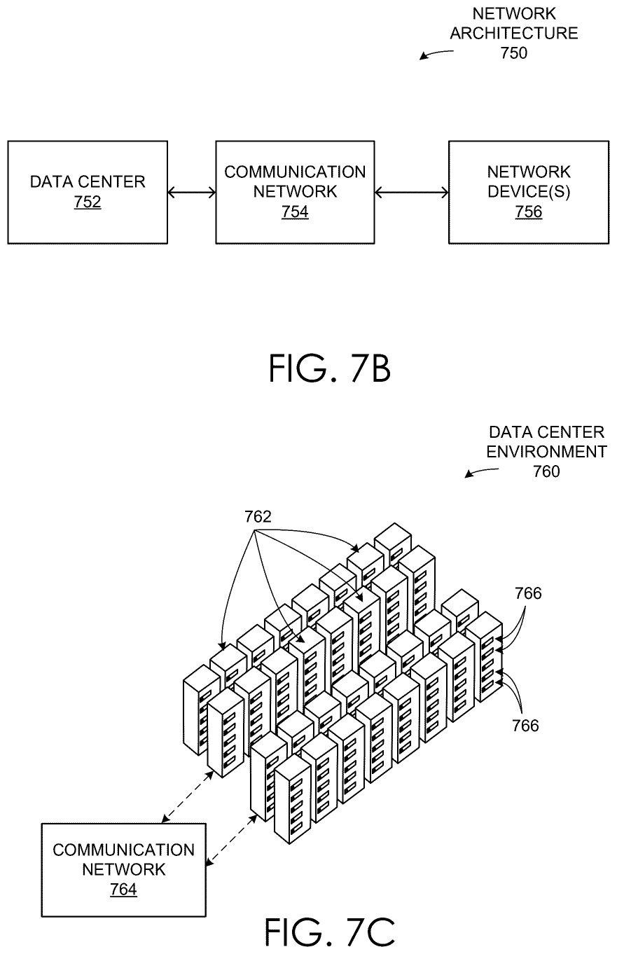

FIG. 7A illustrates an example data center 700, in which at least one embodiment may be used. In at least one embodiment, data center 700 includes a data center infrastructure layer 710, a framework layer 720, a software layer 730, and an application layer 740.

In at least one embodiment, as shown in FIG. 7A, data center infrastructure layer 710 may include a resource orchestrator 712, grouped computing resources 714, and node computing resources (“node C.R.s”) 716(1)-716(N), where “N” represents any whole, positive integer. In at least one embodiment, node C.R.s 716(1)-716(N) may include, but are not limited to, any number of central processing units (“CPUs”) or other processors (including accelerators, field programmable gate arrays (FPGAs), graphics processors, etc.), memory devices (e.g., dynamic read-only memory), storage devices (e.g., solid state or disk drives), network input/output (“NW I/O”) devices, network switches, virtual machines (“VMs”), power modules, and cooling modules, etc. In at least one embodiment, one or more node C.R.s from among node C.R.s 716(1)-716(N) may be a server having one or more of above-mentioned computing resources.

In at least one embodiment, grouped computing resources 714 may include separate groupings of node C.R.s housed within one or more racks (not shown), or many racks housed in data centers at various geographical locations (also not shown). Separate groupings of node C.R.s within grouped computing resources 714 may include grouped compute, network, memory or storage resources that may be configured or allocated to support one or more workloads. In at least one embodiment, several node C.R.s including CPUs or processors may grouped within one or more racks to provide compute resources to support one or more workloads. In at least one embodiment, one or more racks may also include any number of power modules, cooling modules, and network switches, in any combination.

In at least one embodiment, resource orchestrator 712 may configure or otherwise control one or more node C.R.s 716(1)-716(N) and/or grouped computing resources 714. In at least one embodiment, resource orchestrator 712 may include a software design infrastructure (“SDI”) management entity for data center 700. In at least one embodiment, resource orchestrator may include hardware, software or some combination thereof.

In at least one embodiment, as shown in FIG. 7A, framework layer 720 includes a job scheduler 722, a configuration manager 724, a resource manager 726 and a distributed file system 728. In at least one embodiment, framework layer 720 may include a framework to support software 732 of software layer 730 and/or one or more application(s) 742 of application layer 740. In at least one embodiment, software 732 or application(s) 742 may respectively include web-based service software or applications, such as those provided by Amazon Web Services, Google Cloud and Microsoft Azure. In at least one embodiment, framework layer 720 may be, but is not limited to, a type of free and open-source software web application framework such as Apache Spark™ (hereinafter “Spark”) that may use distributed file system 728 for large-scale data processing (e.g., “big data”). In at least one embodiment, job scheduler 722 may include a Spark driver to facilitate scheduling of workloads supported by various layers of data center 700. In at least one embodiment, configuration manager 724 may be capable of configuring different layers such as software layer 730 and framework layer 720 including Spark and distributed file system 728 for supporting large-scale data processing. In at least one embodiment, resource manager 726 may be capable of managing clustered or grouped computing resources mapped to or allocated for support of distributed file system 728 and job scheduler 722. In at least one embodiment, clustered or grouped computing resources may include grouped computing resource 814 at data center infrastructure layer 710. In at least one embodiment, resource manager 726 may coordinate with resource orchestrator 712 to manage these mapped or allocated computing resources.

In at least one embodiment, software 732 included in software layer 730 may include software used by at least portions of node C.R.s 716(1)-716(N), grouped computing resources 714, and/or distributed file system 728 of framework layer 720. The one or more types of software may include, but are not limited to, Internet web page search software, e-mail virus scan software, database software, and streaming video content software.

In at least one embodiment, application(s) 742 included in application layer 740 may include one or more types of applications used by at least portions of node C.R.s 716(1)-716(N), grouped computing resources 714, and/or distributed file system 728 of framework layer 720. One or more types of applications may include, but are not limited to, any number of a genomics application, a cognitive compute, and a machine learning application, including training or inferencing software, machine learning framework software (e.g., PyTorch, TensorFlow, Caffe, etc.) or other machine learning applications used in conjunction with one or more embodiments.

In at least one embodiment, any of configuration manager 724, resource manager 726, and resource orchestrator 712 may implement any number and type of self-modifying actions based on any amount and type of data acquired in any technically feasible fashion. In at least one embodiment, self-modifying actions may relieve a data center operator of data center 700 from making possibly bad configuration decisions and possibly avoiding underused and/or poor performing portions of a data center.

In at least one embodiment, data center 700 may include tools, services, software or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to data center 700. In at least one embodiment, trained machine learning models corresponding to one or more neural networks may be used to infer or predict information using resources described above with respect to data center 700 by using weight parameters calculated through one or more training techniques described herein.

In at least one embodiment, data center may use CPUs, application-specific integrated circuits (ASICs), GPUs, FPGAs, or other hardware to perform training and/or inferencing using above-described resources. Moreover, one or more software and/or hardware resources described above may be configured as a service to allow users to train or performing inferencing of information, such as image recognition, speech recognition, or other artificial intelligence services.

Inference and/or training logic 715 are used to perform inferencing and/or training operations associated with one or more embodiments. In at least one embodiment, inference and/or training logic 715 may be used in system FIG. 7A for inferencing or predicting operations based, at least in part, on weight parameters calculated using neural network training operations, neural network functions and/or architectures, or neural network use cases described herein.

As described above, data centers, high performance computing clusters, and/or the like are often formed of various computing components or networked devices, and communication networks formed of electrical and/or optical devices may be used to enable communication between the networked devices forming these implementations. With reference to FIG. 7B, for example, a network architecture 750 may include a data center 752, a communication network 754, and network device(s) 756. The network architecture 750 may illustrate a general computing architecture within which more specific systems and/or subsystems may function. Although described hereinafter with reference to a network architecture 750 and/or data center 752 within which the embodiments of the present disclosure may be implemented, the present disclosure contemplates that the transceiver resiliency devices and techniques described herein may be applicable to any communication implementation without limitation.

For example, the data center 752 may be a centralized facility designed to house computing resources and related components. The data center 752 may operate to support the infrastructure required for advanced computational tasks, for efficient, secure, and reliable operations. The data center 752 may include the building and structural components, including power supplies, cooling systems, fire suppression systems, and physical security measures that are configured to maintain optimal operating conditions and/or protect the equipment from environmental hazards and unauthorized access. An example data center 752 may include high-performance servers or compute nodes, often arranged in racks, such as those illustrated in FIG. 1B, and connected through high-speed networks as described herein. These servers may include processors (e.g., central processing units (CPUs), graphics processing units (GPUs), data processing units (DPUs) and/or the like), memory (e.g., RAM), and storage solutions (e.g., hard disk drives (HDDs), solid state drives (SSDs), and/or the like. The hardware configuration may be designed for parallel processing and high throughput, catering to the demands of high-performance computing (HPC) applications.

The data center 752 may include high-speed network equipment, such as network switches, routers, firewalls, and/or the like to facilitate fast and secure data transmission within the data center 752 (e.g., between the servers or compute nodes) and between external networks. The data center 752 may facilitate communication between servers or compute nodes through a network topology that ensures efficient data exchange, minimizes latency, and maximizes bandwidth. The network topology may dictate how various network devices, such as switches and routers, are interconnected for data flow. By implementing an effective network topology, the data center 752 may support high-performance computing tasks. Examples of various network topologies may include hierarchical networking topologies such as the fat tree topology, Slim Fly topology, Dragonfly topology, and/or the like.

The communication network 754 may communicably couple the data center 752 with network device(s) 756 and other external devices for data exchange and connectivity. Examples of the communication network 754 may include an Internet Protocol (IP) network, an Ethernet network, an InfiniBand (IB) network, a Fibre Channel network, the Internet, a cellular communication network, a wireless communication network, combinations thereof (e.g., Fibre Channel over Ethernet), variants thereof, and/or the like. The ability of the communication network 754 to incorporate multiple network types and configurations may allow the data center 752 to adapt to diverse application needs, from general data communication to specialized HPC tasks. As described herein, the communication network 754 may leverage various optical components to establish communication links (e.g., communicably couple) between components in the architecture 750. As such, the communication network 754 may include various optical devices, transceivers, modules, and/or the like that are configured to generate optical signals (e.g., provide optical transmitter functionality) and/or receive optical signals (e.g., provide optical receiver functionality).

The network device(s) 756 may include a variety of computing devices capable of transmitting and receiving signals over the communication network 754. The network device(s) 756 may range from personal computing devices to complex server configurations. Examples include Personal Computers (PCs), laptops, tablets, smartphones, and servers. The network device(s) 756 may facilitate user interactions with the data center 752, allowing for data input, retrieval, and processing from remote locations. In addition to individual computing devices, the network device(s) 756 may also include collections of servers or additional data centers. For instance, these could be other data centers similar to or the same as data center 752. Such an interconnection may allow for the formation of a distributed computing environment for improved redundancy, load balancing, and disaster recovery capabilities. By linking multiple data centers, the network architecture 750 may leverage geographically dispersed resources, optimizing performance and ensuring high availability.

As described herein, the data center 752 and/or the network device(s) 756 may include storage devices and processing circuitry for executing computing tasks, such as controlling the flow of data internally and over the communication network 754. The processing circuitry may include software, hardware, or a combination thereof. For example, the processing circuitry may include a memory containing executable instructions and a processor (e.g., a microprocessor) that executes these instructions. The memory may correspond to any suitable type of memory device or collection of memory devices configured to store instructions. Non-limiting examples of suitable memory devices include Flash memory, Random Access Memory (RAM), Read Only Memory (ROM), variants thereof, combinations thereof, or similar technologies. In specific embodiments, the memory and processor may be integrated into a common device, such as a microprocessor with integrated memory. Additionally, or alternatively, the processing circuitry may comprise hardware components, such as an application-specific integrated circuit (ASIC). Other non-limiting examples of processing circuitry include Integrated Circuit (IC) chips, CPUs, GPUs, microprocessors, Field Programmable Gate Arrays (FPGAs), collections of logic gates or transistors, resistors, capacitors, inductors, and diodes. Some or all of the processing circuitry may be provided on a Printed Circuit Board (PCB) or a collection of PCBs. It should be appreciated that any appropriate type of electrical component or collection of electrical components may be suitable for inclusion in the processing circuitry.

In addition, although not explicitly shown, the present disclosure contemplates that the data center 752 and network device(s) 756 may include one or more communication interfaces for facilitating wired and/or wireless communication between one another and other unillustrated elements of the network architecture 750. These communication interfaces may include a variety of technologies, including but not limited to Ethernet ports, fiber optic connections, Wi-Fi® transceivers, Bluetooth® modules, and cellular communication modules for integration and interoperability among the various components within the network architecture 750.

Furthermore, the present disclosure contemplates that the network architecture 750 may include additional components and functionalities. For example, the network architecture may include, without limitation, additional processing units, specialized accelerators (such as Tensor Processing Units or TPUs), enhanced security modules, and redundant power supplies. The inclusion of these elements may be intended to ensure that the network architecture 750 is robust, scalable, and capable of meeting diverse operational requirements. Any variations, modifications, or adaptations of the described elements that fall within the spirit and scope of the disclosure are considered to be encompassed by the present disclosure. This includes any combinations, sub-combinations, or enhancements of the various described elements to achieve improved performance, reliability, and efficiency in the network architecture 750.

In high-capacity data center networks, such as those illustrated in FIGS. 7B-7C, the communication network 754 may leverage optical transceivers that transmit and receive optical signals over optical fibers or other optical communication mediums in order to establish connection between devices in the network architecture 750.

With reference to FIG. 7C, in at least one example embodiment, the data center 762 corresponds to a collection of network devices, such as network switches (e.g., Ethernet switches) connected with a collection of servers or compute nodes. The data center 762 may adhere to a networking topology (e.g., a hierarchal networking topology), such as a fat tree topology, a Slim Fly topology, a Dragonfly topology, and/or the like. The data center 762 routes traffic amongst the network switches and servers therein, and at least one layer of the topology in the data center 762 is coupled to the communication network 764 to allow networking traffic to flow between the data center 762 and the network device(s) 766.

The communication network 764 may communicably couple the data center 762 with network device(s) 766 and other external devices for data exchange and connectivity. Examples of the communication network 764 may include an Internet Protocol (IP) network, an Ethernet network, an InfiniBand (IB) network, a Fibre Channel network, the Internet, a cellular communication network, a wireless communication network, combinations thereof (e.g., Fibre Channel over Ethernet), variants thereof, and/or the like.

In one specific but non-limiting example, the communication network 764 is a network that enables data transmission between the device(s) 766 using data signals (e.g., digital, optical, wireless signals).

Each type of network offers specific advantages tailored to different operational requirements. For instance, an IP network or Ethernet network may provide widespread compatibility and ease of integration, supporting various protocols and applications across the data center 762 and the network device(s) 766 (and/or external devices). An InfiniBand network may offer high throughput and low latency, ideal for HPC environments where rapid data transfer and minimal delay are required. Fibre Channel networks may be employed for their robust performance in storage area networks (SANs), ensuring fast and reliable access to storage resources. Cellular and wireless communication networks may be used to extend connectivity to remote or mobile devices for increased flexibility and accessibility.

The ability of the communication network 764 to incorporate multiple network types and configurations allows the data center 762 to adapt to diverse application needs, from general data communication to specialized HPC tasks. Examples of the communication network 764 that may be used to connect the data center 762 and the network device(s) 766 include an Internet Protocol (IP) network, an Ethernet network, an InfiniBand (TB) network, a Fibre Channel network, the Internet, a cellular communication network, a wireless communication network, combinations thereof (e.g., Fibre Channel over Ethernet), variants thereof, and/or the like.

The network device(s) 766 may include a variety of computing devices capable of sending and receiving signals over the communication network 764. The network device(s) 766 can range from personal computing devices to complex server configurations. Examples include Personal Computers (PCs), laptops, tablets, smartphones, and servers. The network device(s) 766 may facilitate user interactions with the data center 762, allowing for data input, retrieval, and processing from remote locations. In addition to individual computing devices, the network device(s) 766 may also include collections of servers or additional data centers. For instance, these could be other data centers similar to or the same as data center 762. Such an interconnection may allow for the formation of a distributed computing environment for improved redundancy, load balancing, and disaster recovery capabilities. By linking multiple data centers, the data center environment 760 can leverage geographically dispersed resources, optimizing performance and ensuring high availability.

The one or more network devices 766 may include one or more of Personal Computer (PC), a laptop, a tablet, a smartphone, a server, a collection of servers, and/or any suitable computing device for sending and receiving signals over the communication network 764. In at least one example embodiment, the one or more network device(s) 766 correspond to another data center, similar to or the same as data center 762.

As noted above, the data center 762 and/or the network device(s) 766 may include storage devices and/or processing circuitry for carrying out computing tasks, for example, tasks associated with controlling the flow of data internally and/or over the communication network 764. Such processing circuitry may comprise software, hardware, or a combination thereof. For example, the processing circuitry may include a memory including executable instructions and a processor (e.g., a microprocessor) that executes the instructions on the memory. The memory may correspond to any suitable type of memory device or collection of memory devices configured to store instructions. Non-limiting examples of suitable memory devices that may be used include Flash memory, Random Access Memory (RAM), Read Only Memory (ROM), variants thereof, combinations thereof, or the like. In some embodiments, the memory and processor may be integrated into a common device (e.g., a microprocessor may include integrated memory). Additionally or alternatively, the processing circuitry may comprise hardware, such as an application specific integrated circuit (ASIC). Other non-limiting examples of the processing circuitry include an Integrated Circuit (IC) chip, a Central Processing Unit (CPU), a Graphics Processing Unit (GPU), a microprocessor, a Field Programmable Gate Array (FPGA), a collection of logic gates or transistors, resistors, capacitors, inductors, diodes, or the like. Some or all of the processing circuitry may be provided on a Printed Circuit Board (PCB) or collection of PCBs. It should be appreciated that any appropriate type of electrical component or collection of electrical components may be suitable for inclusion in the processing circuitry.

In addition, although not explicitly shown, it should be appreciated that the data center 762 and network device(s) 766 may include one or more communication interfaces for facilitating wired and/or wireless communication between one another and other unillustrated elements of the data center environment 760. These communication interfaces may include a variety of technologies, including but not limited to Ethernet ports, fiber optic connections, Wi-Fi® transceivers, Bluetooth® modules, and cellular communication modules for integration and interoperability among the various components within the data center environment 760. Furthermore, it should be understood that the data center environment 760 may include additional components and functionalities within the scope of the present disclosure. These components may comprise, without limitation, additional processing units, specialized accelerators (such as Tensor Processing Units or TPUs), enhanced security modules, and redundant power supplies. The inclusion of these elements is intended to ensure that the data center environment 760 is robust, scalable, and capable of meeting diverse operational requirements. Any variations, modifications, or adaptations of the described elements that fall within the spirit and scope of the disclosure are considered to be encompassed by the present disclosure. This includes any combinations, sub-combinations, or enhancements of the various described elements to achieve improved performance, reliability, and efficiency in the data center environment 760.

Such components can be used for stackable transceiver panel structures and modular guides to route network cable harnesses in layers.

### Computer Systems

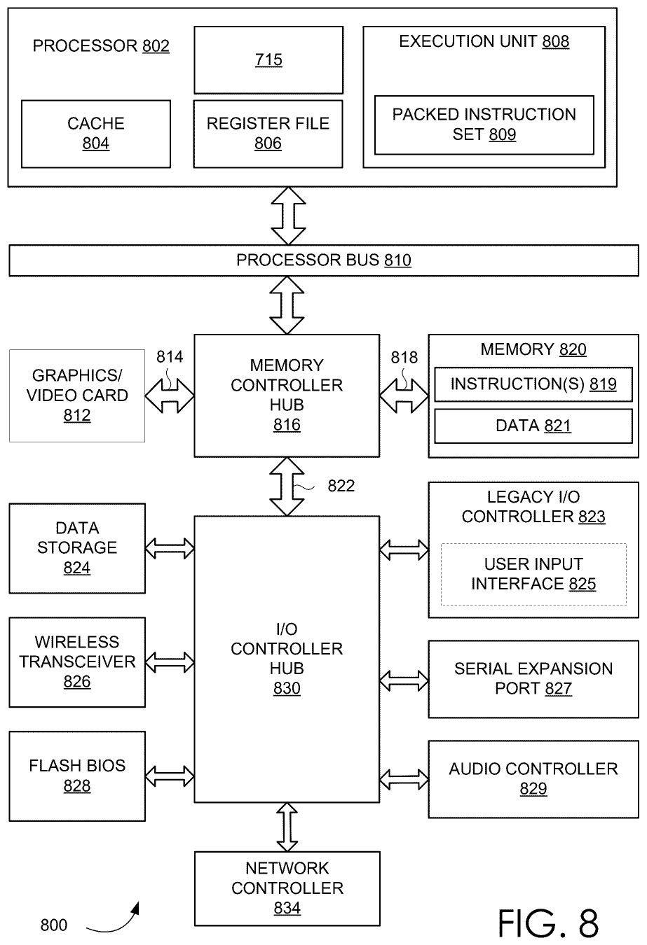

FIG. 8 is a block diagram illustrating an exemplary computer system, which may be a system with interconnected devices and components, a system-on-a-chip (SOC) or some combination thereof 800 formed with a processor that may include execution units to execute an instruction, according to at least one embodiment. In at least one embodiment, computer system 800 may include, without limitation, a component, such as a processor 802 to employ execution units including logic to perform algorithms for process data, in accordance with present disclosure, such as in embodiment described herein. In at least one embodiment, computer system 800 may include processors, such as PENTIUM® Processor family, Xeon™, Itanium®, XScale™ and/or StrongARM™, Intel® Core™, or Intel® Nervana™ microprocessors available from Intel Corporation of Santa Clara, California, although other systems (including PCs having other microprocessors, engineering workstations, set-top boxes and like) may also be used. In at least one embodiment, computer system 800 may execute a version of WINDOWS' operating system available from Microsoft Corporation of Redmond, Wash., although other operating systems (UNIX and Linux for example), embedded software, and/or graphical user interfaces, may also be used.

Embodiments may be used in other devices such as handheld devices and embedded applications. Some examples of handheld devices include cellular phones, Internet Protocol devices, digital cameras, personal digital assistants (“PDAs”), and handheld PCs. In at least one embodiment, embedded applications may include a microcontroller, a digital signal processor (“DSP”), system on a chip, network computers (“NetPCs”), set-top boxes, network hubs, wide area network (“WAN”) switches, or any other system that may perform one or more instructions in accordance with at least one embodiment.

In at least one embodiment, computer system 800 may include, without limitation, processor 802 that may include, without limitation, one or more execution units 808 to perform machine learning model training and/or inferencing according to techniques described herein. In at least one embodiment, computer system 800 is a single processor desktop or server system, but in another embodiment computer system 800 may be a multiprocessor system. In at least one embodiment, processor 802 may include, without limitation, a complex instruction set computer (“CISC”) microprocessor, a reduced instruction set computing (“RISC”) microprocessor, a very long instruction word (“VLIW”) microprocessor, a processor implementing a combination of instruction sets, or any other processor device, such as a digital signal processor, for example. In at least one embodiment, processor 802 may be coupled to a processor bus 810 that may transmit data signals between processor 802 and other components in computer system 800.

In at least one embodiment, processor 802 may include, without limitation, a Level 1 (“L1”) internal cache memory (“cache”) 804. In at least one embodiment, processor 802 may have a single internal cache or multiple levels of internal cache. In at least one embodiment, cache memory may reside external to processor 802. Other embodiments may also include a combination of both internal and external caches depending on particular implementation and needs. In at least one embodiment, register file 806 may store different types of data in various registers including, without limitation, integer registers, floating point registers, status registers, and instruction pointer register.

In at least one embodiment, execution unit 808, including, without limitation, logic to perform integer and floating point operations, also resides in processor 802. In at least one embodiment, processor 802 may also include a microcode (“ucode”) read only memory (“ROM”) that stores microcode for certain macro instructions. In at least one embodiment, execution unit 808 may include logic to handle a packed instruction set 809. In at least one embodiment, by including packed instruction set 809 in an instruction set of a general-purpose processor 802, along with associated circuitry to execute instructions, operations used by many multimedia applications may be performed using packed data in a general-purpose processor 802. In one or more embodiments, many multimedia applications may be accelerated and executed more efficiently by using full width of a processor's data bus for performing operations on packed data, which may eliminate need to transfer smaller units of data across processor's data bus to perform one or more operations one data element at a time.

In at least one embodiment, execution unit 808 may also be used in microcontrollers, embedded processors, graphics devices, DSPs, and other types of logic circuits. In at least one embodiment, computer system 800 may include, without limitation, a memory 820. In at least one embodiment, memory 820 may be implemented as a Dynamic Random Access Memory (“DRAM”) device, a Static Random Access Memory (“SRAM”) device, flash memory device, or other memory device. In at least one embodiment, memory 820 may store instruction(s) 819 and/or data 821 represented by data signals that may be executed by processor 802.

In at least one embodiment, system logic chip may be coupled to processor bus 810 and memory 820. In at least one embodiment, system logic chip may include, without limitation, a memory controller hub (“MCH”) 816, and processor 802 may communicate with MCH 816 via processor bus 810. In at least one embodiment, MCH 816 may provide a high bandwidth memory path 818 to memory 820 for instruction and data storage and for storage of graphics commands, data and textures. In at least one embodiment, MCH 816 may direct data signals between processor 802, memory 820, and other components in computer system 800 and to bridge data signals between processor bus 810, memory 820, and a system I/O 822. In at least one embodiment, system logic chip may provide a graphics port for coupling to a graphics controller. In at least one embodiment, MCH 816 may be coupled to memory 820 through a high bandwidth memory path 818 and graphics/video card 812 may be coupled to MCH 816 through an Accelerated Graphics Port (“AGP”) interconnect 814.

In at least one embodiment, computer system 800 may use system I/O 822 that is a proprietary hub interface bus to couple MCH 816 to I/O controller hub (“ICH”) 830. In at least one embodiment, ICH 830 may provide direct connections to some I/O devices via a local I/O bus. In at least one embodiment, local I/O bus may include, without limitation, a high-speed I/O bus for connecting peripherals to memory 820, chipset, and processor 802. Examples may include, without limitation, an audio controller 829, a firmware hub (“flash BIOS”) 828, a wireless transceiver 826, a data storage 824, a legacy I/O controller 823 containing user input and keyboard interface(s) 825, a serial expansion port 827, such as Universal Serial Bus (“USB”), and a network controller 834. Data storage 824 may comprise a hard disk drive, a floppy disk drive, a CD-ROM device, a flash memory device, or other mass storage device.

In at least one embodiment, FIG. 8 illustrates a system, which includes interconnected hardware devices or “chips”, whereas in other embodiments, FIG. 8 may illustrate an exemplary System on a Chip (“SoC”). In at least one embodiment, devices may be interconnected with proprietary interconnects, standardized interconnects (e.g., PCIe) or some combination thereof. In at least one embodiment, one or more components of computer system 800 are interconnected using compute express link (CXL) interconnects.

Inference and/or training logic 715 are used to perform inferencing and/or training operations associated with one or more embodiments. In at least one embodiment, inference and/or training logic 715 may be used in system FIG. 8 for inferencing or predicting operations based, at least in part, on weight parameters calculated using neural network training operations, neural network functions and/or architectures, or neural network use cases described herein.

Such components can be used for stackable transceiver panel structures and modular guides to route network cable harnesses in layers.

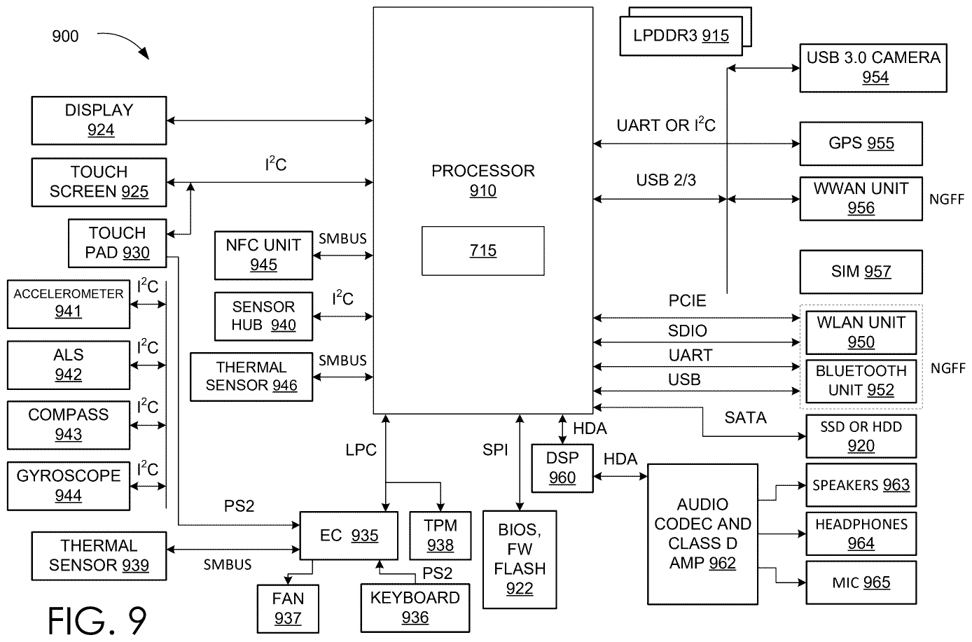

FIG. 9 is a block diagram illustrating an electronic device 900 for utilizing a processor 910, according to at least one embodiment. In at least one embodiment, electronic device 900 may be, for example and without limitation, a notebook, a tower server, a rack server, a blade server, a laptop, a desktop, a tablet, a mobile device, a phone, an embedded computer, or any other suitable electronic device.

In at least one embodiment, electronic device 900 may include, without limitation, processor 910 communicatively coupled to any suitable number or kind of components, peripherals, modules, or devices. In at least one embodiment, processor 910 coupled using a bus or interface, such as a 1° C. bus, a System Management Bus (“SMBus”), a Low Pin Count (LPC) bus, a Serial Peripheral Interface (“SPI”), a High Definition Audio (“HDA”) bus, a Serial Advance Technology Attachment (“SATA”) bus, a Universal Serial Bus (“USB”) (versions 1, 2, 3), or a Universal Asynchronous Receiver/Transmitter (“UART”) bus. In at least one embodiment, FIG. 9 illustrates a system, which includes interconnected hardware devices or “chips”, whereas in other embodiments, FIG. 9 may illustrate an exemplary System on a Chip (“SoC”). In at least one embodiment, devices illustrated in FIG. 9 may be interconnected with proprietary interconnects, standardized interconnects (e.g., PCIe) or some combination thereof. In at least one embodiment, one or more components of FIG. 9 are interconnected using compute express link (CXL) interconnects.

In at least one embodiment, FIG. 9 may include a display 924, a touch screen 925, a touch pad 930, a Near Field Communications unit (“NFC”) 945, a sensor hub 940, a thermal sensor 946, an Express Chipset (“EC”) 935, a Trusted Platform Module (“TPM”) 938, BIOS/firmware/flash memory (“BIOS, FW Flash”) 922, a DSP 960, a drive 920 such as a Solid State Disk (“SSD”) or a Hard Disk Drive (“HDD”), a wireless local area network unit (“WLAN”) 950, a Bluetooth unit 952, a Wireless Wide Area Network unit (“WWAN”) 956, a Global Positioning System (GPS) 955, a camera (“USB 3.0 camera”) 954 such as a USB 3.0 camera, and/or a Low Power Double Data Rate (“LPDDR”) memory unit (“LPDDR3”) 915 implemented in, for example, LPDDR3 standard. These components may each be implemented in any suitable manner.

In at least one embodiment, other components may be communicatively coupled to processor 910 through components discussed above. In at least one embodiment, an accelerometer 941, Ambient Light Sensor (“ALS”) 942, compass 943, and a gyroscope 944 may be communicatively coupled to sensor hub 940. In at least one embodiment, thermal sensor 939, a fan 937, a keyboard 936, and a touch pad 930 may be communicatively coupled to EC 935. In at least one embodiment, speakers 963, headphones 964, and microphone (“mic”) 965 may be communicatively coupled to an audio unit (“audio codec and class d amp”) 962, which may in turn be communicatively coupled to DSP 960. In at least one embodiment, audio unit 964 may include, for example and without limitation, an audio coder/decoder (“codec”) and a class D amplifier. In at least one embodiment, SIM card (“SIM”) 957 may be communicatively coupled to WWAN unit 956. In at least one embodiment, components such as WLAN unit 950 and Bluetooth unit 952, as well as WWAN unit 956 may be implemented in a Next Generation Form Factor (“NGFF”).

Inference and/or training logic 715 are used to perform inferencing and/or training operations associated with one or more embodiments. In at least one embodiment, inference and/or training logic 715 may be used in system FIG. 9 for inferencing or predicting operations based, at least in part, on weight parameters calculated using neural network training operations, neural network functions and/or architectures, or neural network use cases described herein.

Such components can be used for stackable transceiver panel structures and modular guides to route network cable harnesses in layers.

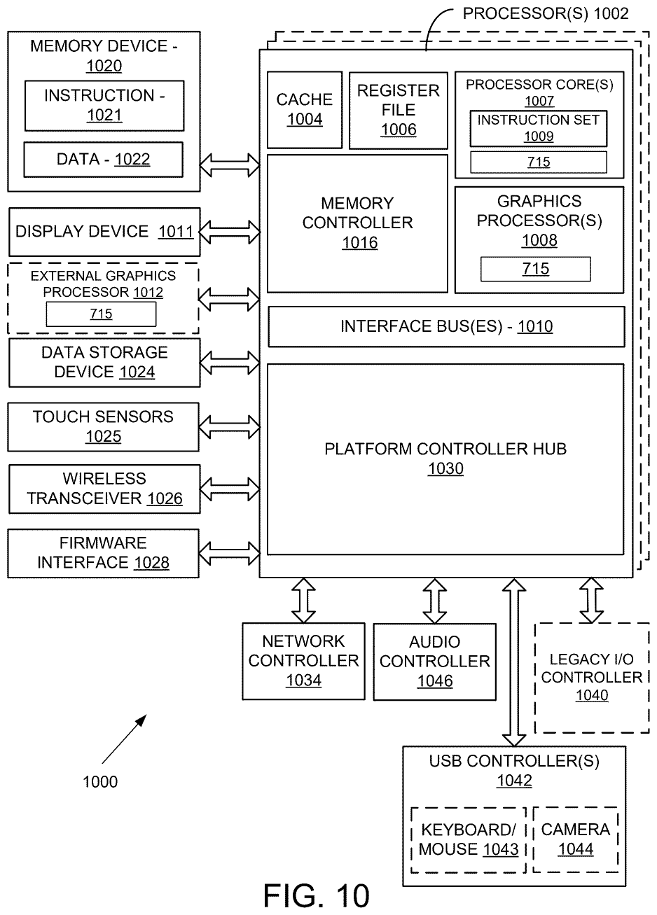

FIG. 10 is a block diagram of a processing system, according to at least one embodiment. In at least one embodiment, system 1000 includes one or more processor(s) 1002 and one or more graphics processor(s) 1008, and may be a single processor desktop system, a multiprocessor workstation system, or a server system having a large number of processor(s) 1002 or processor core(s) 1007. In at least one embodiment, system 1000 is a processing platform incorporated within a system-on-a-chip (SoC) integrated circuit for use in mobile, handheld, or embedded devices.

In at least one embodiment, system 1000 can include, or be incorporated within a server-based gaming platform, a game console, including a game and media console, a mobile gaming console, a handheld game console, or an online game console. In at least one embodiment, system 1000 is a mobile phone, smart phone, tablet computing device or mobile Internet device. In at least one embodiment, processing system 1000 can also include, couple with, or be integrated within a wearable device, such as a smart watch wearable device, smart eyewear device, augmented reality device, or virtual reality device. In at least one embodiment, processing system 1000 is a television or set top box device having one or more processor(s) 1002 and a graphical interface generated by one or more graphics processor(s) 1008.

In at least one embodiment, one or more processor(s) 1002 each include one or more processor core(s) 1007 to process instructions which, when executed, perform operations for system and user software. In at least one embodiment, each of one or more processor core(s) 1007 is configured to process a specific instruction set 1009. In at least one embodiment, instruction set 1009 may facilitate Complex Instruction Set Computing (CISC), Reduced Instruction Set Computing (RISC), or computing via a Very Long Instruction Word (VLIW). In at least one embodiment, processor core(s) 1007 may each process a different instruction set 1009, which may include instructions to facilitate emulation of other instruction sets. In at least one embodiment, processor core(s) 1007 may also include other processing devices, such a Digital Signal Processor (DSP).

In at least one embodiment, processor(s) 1002 includes cache memory 1004. In at least one embodiment, processor(s) 1002 can have a single internal cache or multiple levels of internal cache. In at least one embodiment, cache memory is shared among various components of processor(s) 1002. In at least one embodiment, processor(s) 1002 also uses an external cache (e.g., a Level-3 (L3) cache or Last Level Cache (LLC)) (not shown), which may be shared among processor core(s) 1007 using known cache coherency techniques. In at least one embodiment, register file 1006 is additionally included in processor(s) 1002 which may include different types of registers for storing different types of data (e.g., integer registers, floating point registers, status registers, and an instruction pointer register). In at least one embodiment, register file 1006 may include general-purpose registers or other registers.

In at least one embodiment, one or more processor(s) 1002 are coupled with one or more interface bus(es) 1010 to transmit communication signals such as address, data, or control signals between processor(s) 1002 and other components in system 1000. In at least one embodiment, interface bus(es) 1010, in one embodiment, can be a processor bus, such as a version of a Direct Media Interface (DMI) bus. In at least one embodiment, interface bus(es) 1010 is not limited to a DMI bus, and may include one or more Peripheral Component Interconnect buses (e.g., PCI, PCI Express), memory busses, or other types of interface busses. In at least one embodiment processor(s) 1002 include an integrated memory controller 1016 and a platform controller hub 1030. In at least one embodiment, memory controller 1016 facilitates communication between a memory device and other components of system 1000, while platform controller hub (PCH) 1030 provides connections to I/O devices via a local I/O bus.

In at least one embodiment, memory device 1020 can be a dynamic random access memory (DRAM) device, a static random access memory (SRAM) device, flash memory device, phase-change memory device, or some other memory device having suitable performance to serve as process memory. In at least one embodiment memory device 1020 can operate as system memory for system 1000, to store data 1022 and instruction 1021 for use when one or more processor(s) 1002 executes an application or process. In at least one embodiment, memory controller 1016 also couples with an optional external graphics processor 1012, which may communicate with one or more graphics processor(s) 1008 in processor(s) 1002 to perform graphics and media operations. In at least one embodiment, a display device 1011 can connect to processor(s) 1002. In at least one embodiment display device 1011 can include one or more of an internal display device, as in a mobile electronic device or a laptop device or an external display device attached via a display interface (e.g., DisplayPort, etc.). In at least one embodiment, display device 1011 can include a head mounted display (HMD) such as a stereoscopic display device for use in virtual reality (VR) applications or augmented reality (AR) applications.

In at least one embodiment, platform controller hub 1030 enables peripherals to connect to memory device 1020 and processor(s) 1002 via a high-speed I/O bus. In at least one embodiment, I/O peripherals include, but are not limited to, an audio controller 1046, a network controller 1034, a firmware interface 1028, a wireless transceiver 1026, touch sensors 1025, a data storage device 1024 (e.g., hard disk drive, flash memory, etc.). In at least one embodiment, data storage device 1024 can connect via a storage interface (e.g., SATA) or via a peripheral bus, such as a Peripheral Component Interconnect bus (e.g., PCI, PCI Express). In at least one embodiment, touch sensors 1025 can include touch screen sensors, pressure sensors, or fingerprint sensors. In at least one embodiment, wireless transceiver 1026 can be a Wi-Fi transceiver, a Bluetooth transceiver, or a mobile network transceiver such as a 3G, 4G, or Long Term Evolution (LTE) transceiver. In at least one embodiment, firmware interface 1028 enables communication with system firmware, and can be, for example, a unified extensible firmware interface (UEFI). In at least one embodiment, network controller 1034 can enable a network connection to a wired network. In at least one embodiment, a high-performance network controller (not shown) couples with interface bus(es) 1010. In at least one embodiment, audio controller 1046 is a multi-channel high definition audio controller. In at least one embodiment, system 1000 includes an optional legacy I/O controller 1040 for coupling legacy (e.g., Personal System 2 (PS/2)) devices to system. In at least one embodiment, platform controller hub 1030 can also connect to one or more Universal Serial Bus (USB) controller(s) 1042 connect input devices, such as keyboard and mouse 1043 combinations, a camera 1044, or other USB input devices.

In at least one embodiment, an instance of memory controller 1016 and platform controller hub 1030 may be integrated into a discreet external graphics processor, such as external graphics processor 1012. In at least one embodiment, platform controller hub 1030 and/or memory controller 1016 may be external to one or more processor(s) 1002. For example, in at least one embodiment, system 1000 can include an external memory controller 1016 and platform controller hub 1030, which may be configured as a memory controller hub and peripheral controller hub within a system chipset that is in communication with processor(s) 1002.

Inference and/or training logic 715 are used to perform inferencing and/or training operations associated with one or more embodiments. In at least one embodiment portions or all of inference and/or training logic 715 may be incorporated into graphics processor(s) 1008. For example, in at least one embodiment, training and/or inferencing techniques described herein may use one or more of ALUs embodied in a graphics processor. In at least one embodiment, weight parameters may be stored in on-chip or off-chip memory and/or registers (shown or not shown) that configure ALUs of a graphics processor to perform one or more machine learning algorithms, neural network architectures, use cases, or training techniques described herein.

Such components can be used for stackable transceiver panel structures and modular guides to route network cable harnesses in layers.

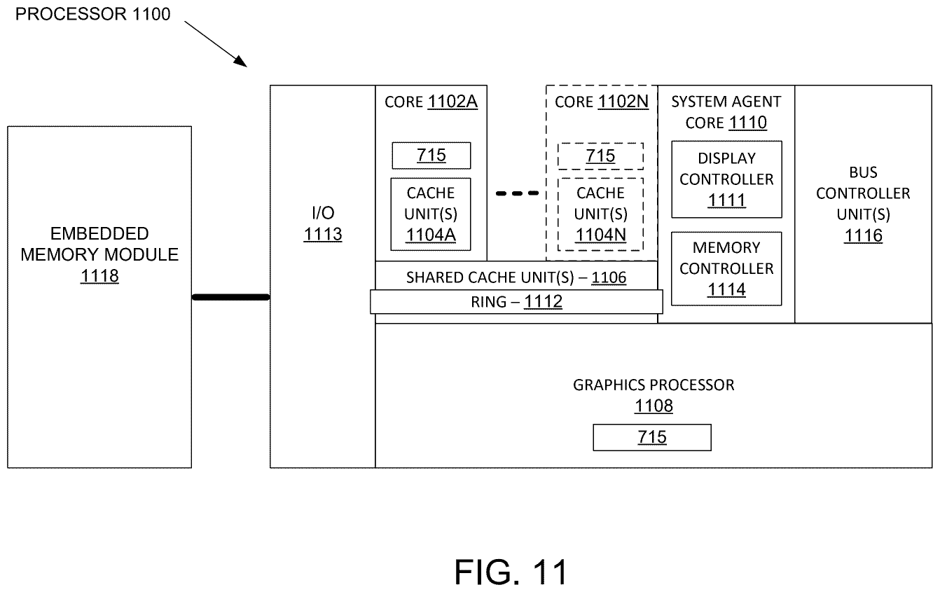

FIG. 11 is a block diagram of a processor 1100 having one or more processor core(s) 1102A-1102N, an integrated memory controller 1114, and an integrated graphics processor 1108, according to at least one embodiment. In at least one embodiment, processor 1100 can include additional cores up to and including additional core 1102N represented by dashed lined boxes. In at least one embodiment, each of processor core(s) 1102A-1102N includes one or more internal cache unit(s) 1104A-1104N. In at least one embodiment, each processor core also has access to one or more shared cached unit(s) 1106.

In at least one embodiment, internal cache unit(s) 1104A-1104N and shared cache unit(s) 1106 represent a cache memory hierarchy within processor 1100. In at least one embodiment, cache unit(s) 1104A-1104N may include at least one level of instruction and data cache within each processor core and one or more levels of shared mid-level cache, such as a Level 2 (L2 ), Level 3 (L3 ), Level 4 (L4 ), or other levels of cache, where a highest level of cache before external memory is classified as an LLC. In at least one embodiment, cache coherency logic maintains coherency between various cache unit(s) 1106 and 1104A-1104N.

In at least one embodiment, processor 1100 may also include a set of one or more bus controller unit(s) 1116 and a system agent core 1110. In at least one embodiment, one or more bus controller unit(s) 1116 manage a set of peripheral buses, such as one or more PCI or PCI express busses. In at least one embodiment, system agent core 1110 provides management functionality for various processor components. In at least one embodiment, system agent core 1110 includes one or more integrated memory controllers 1114 to manage access to various external memory devices (not shown).

In at least one embodiment, one or more of processor core(s) 1102A-1102N include support for simultaneous multi-threading. In at least one embodiment, system agent core 1110 includes components for coordinating and operating processor core(s) 1102A-1102N during multi-threaded processing. In at least one embodiment, system agent core 1110 may additionally include a power control unit (PCU), which includes logic and components to regulate one or more power states of processor core(s) 1102A-1102N and graphics processor 1108.

In at least one embodiment, processor 1100 additionally includes graphics processor 1108 to execute graphics processing operations. In at least one embodiment, graphics processor 1108 couples with shared cache unit(s) 1106, and system agent core 1110, including one or more integrated memory controllers 1114. In at least one embodiment, system agent core 1110 also includes a display controller 1111 to drive graphics processor output to one or more coupled displays. In at least one embodiment, display controller 1111 may also be a separate module coupled with graphics processor 1108 via at least one interconnect, or may be integrated within graphics processor 1108.

In at least one embodiment, a ring based interconnect unit 1112 is used to couple internal components of processor 1100. In at least one embodiment, an alternative interconnect unit may be used, such as a point-to-point interconnect, a switched interconnect, or other techniques. In at least one embodiment, graphics processor 1108 couples with ring based interconnect unit 1112 via an I/O link 1113.

In at least one embodiment, I/O link 1113 represents at least one of multiple varieties of I/O interconnects, including an on package I/O interconnect which facilitates communication between various processor components and a high-performance embedded memory module 1118, such as an eDRAM module. In at least one embodiment, each of processor core(s) 1102A-1102N and graphics processor 1108 use embedded memory modules 1118 as a shared Last Level Cache.

In at least one embodiment, processor core(s) 1102A-1102N are homogenous cores executing a common instruction set architecture. In at least one embodiment, processor core(s) 1102A-1102N are heterogeneous in terms of instruction set architecture (ISA), where one or more of processor core(s) 1102A-1102N execute a common instruction set, while one or more other cores of processor core(s) 1102A-1102N executes a subset of a common instruction set or a different instruction set. In at least one embodiment, processor core(s) 1102A-1102N are heterogeneous in terms of microarchitecture, where one or more cores having a relatively higher power consumption couple with one or more power cores having a lower power consumption. In at least one embodiment, processor 1100 can be implemented on one or more chips or as an SoC integrated circuit.

Inference and/or training logic 715 are used to perform inferencing and/or training operations associated with one or more embodiments. In at least one embodiment portions or all of inference and/or training logic 715 may be incorporated into processor 1100. For example, in at least one embodiment, training and/or inferencing techniques described herein may use one or more of ALUs embodied in graphics processor 1108, processor core(s) 1102A-1102N, or other components in FIG. 11. In at least one embodiment, weight parameters may be stored in on-chip or off-chip memory and/or registers (shown or not shown) that configure ALUs of graphics processor 1100/1108 to perform one or more machine learning algorithms, neural network architectures, use cases, or training techniques described herein.

Such components can be used for stackable transceiver panel structures and modular guides to route network cable harnesses in layers.

Various embodiments can be described by the following clauses:
1. A system, comprising:
   a network switch;
   one or more layered circuit boards to receive inputs to be provided to the network switch;
   one or more layered cable sets to connect corresponding ones of the one or more layered circuit boards and the network switch; and
   one or more layers of a routing cartridge to route corresponding ones of the one or more layered cable sets between the corresponding one or more layered circuit boards and the network switch.
2. The system of clause 1, wherein the one or more layered circuit boards are attached to the routing cartridge.
3. The system of clause 1, further comprising:
   a plurality of ports, located on the one or more layered circuit boards, to connect with external devices that provide at least some of the inputs.
4. The system of clause 1, wherein at least one of the cable sets are within a harness.
5. The system of clause 1, further comprising:
   one or more devices to provide liquid cooling or air cooling for at least a portion of the network switch and for at least a portion of the one or more layered circuit boards.
6. The system of clause 5, wherein the one or more devices provide liquid cooling and are adjacent, between the one or more layered circuit boards and the network switch, to at least a portion of the routing cartridge.
7. The system of clause 5, wherein the one or more devices provide air-cooling and the routing cartridge includes at least one opening to allow airflow from the device to pass between the one or more layered circuit boards and the network switch.
8. The system of clause 1, wherein the one or more layered cable sets connect with one or more devices of the network switch.
9. A method comprising:
   receiving, along one or more paths of a composite routing cartridge, a plurality of cables having opposing ends extending out from the composite routing cartridge;
   securing the plurality of cables to the composite routing cartridge; and
   providing the plurality of cables secured to the composite routing cartridge for a network connection.
10. The method of clause 9, further comprising:
   connecting a first end of at least a portion of the plurality of cables to a front section of a server assembly; and
   connecting a second end of at least the portion of the plurality of cables to a rear section of a server assembly.
11. The method of clause 10, wherein the first end is connected to the front section of the server assembly before the plurality of cables are received along the one or more paths.
12. The method of clause 10, further comprising:
   color coding a first end and a second end of at least a portion of the plurality of cables.
13. The method of clause 9, wherein the composite routing cartridge includes two or more separate sections having fixtures to retain portions of the plurality of cables to the individual sections.
14. The method of clause 9, wherein one or more of the paths are positioned at least partially in separate parallel layers.
15. The method of clause 9, wherein one or more of the paths are across two or more perpendicular planes.
16. A network cable management device comprising:
   a variety of modular pieces combinable to change grouping and orientation between one or more planes for at least a portion of a plurality of network cables, positioned through the variety of modular pieces, when combining the variety of modular pieces.
17. The network cable management device of clause 16, wherein the plurality of network cables are positioned into the variety of modular pieces, from a stack of printed circuit board (PCB) cards, on a plurality of parallel planes.
18. The network cable management device of clause 16, further comprising:
   at least one additional modular piece combinable with the variety of modular pieces to maintain at least one grouping or orientation change.
19. The network cable management device of clause 16, the variety of modular pieces further comprising:
   one or more sections to be affixed to a network device connected to at least one of the plurality of network cables.
20. The network cable management device of clause 16, wherein the variety of modular pieces include one or more openings to allow airflow to pass through the network cable management device and the one or more opening separate from the plurality of network cables.
21. The network cable management device of clause 16, wherein one or more of the variety of modular pieces comprise reinforced plastic.
22. A system, comprising:
   a network including a network switch and a plurality of layered transceiver panel structures, wherein the plurality of layered transceiver panel structures further comprises:
      one or more transceiver cages including a plurality of transceivers to communicably couple the network switch with the plurality of layered transceiver panel structures; and
      one or more structural supports between at least two layers of the plurality of layered transceiver panel structures.

Other variations are within spirit of present disclosure. Thus, while disclosed techniques are susceptible to various modifications and alternative constructions, certain illustrated embodiments thereof are shown in drawings and have been described above in detail. It should be understood, however, that there is no intention to limit disclosure to specific form or forms disclosed, but on contrary, intention is to cover all modifications, alternative constructions, and equivalents falling within spirit and scope of disclosure, as defined in appended claims.

Use of terms “a” and “an” and “the” and similar referents in context of describing disclosed embodiments (especially in context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. Term “connected,” when unmodified and referring to physical connections, is to be construed as partly or wholly contained within, attached to, or joined together, even if there is something intervening. Recitation of ranges of values herein are merely intended to serve as a shorthand method of referring individually to each separate value falling within range, unless otherwise indicated herein and each separate value is incorporated into specification as if it were individually recited herein. Use of term “set” (e.g., “a set of items”) or “subset,” unless otherwise noted or contradicted by context, is to be construed as a nonempty collection comprising one or more members. Further, unless otherwise noted or contradicted by context, term “subset” of a corresponding set does not necessarily denote a proper subset of corresponding set, but subset and corresponding set may be equal.

Conjunctive language, such as phrases of form “at least one of A, B, and C,” or “at least one of A, B and C,” unless specifically stated otherwise or otherwise clearly contradicted by context, is otherwise understood with context as used in general to present that an item, term, etc., may be either A or B or C, or any nonempty subset of set of A and B and C. For instance, in illustrative example of a set having three members, conjunctive phrases “at least one of A, B, and C” and “at least one of A, B and C” refer to any of following sets: {A}, {B}, {C}, {A, B}, {A, C}, {B, C}, {A, B, C}. Thus, such conjunctive language is not generally intended to imply that certain embodiments require at least one of A, at least one of B, and at least one of C each to be present. In addition, unless otherwise noted or contradicted by context, term “plurality” indicates a state of being plural (e.g., “a plurality of items” indicates multiple items). A plurality is at least two items, but can be more when so indicated either explicitly or by context. Further, unless stated otherwise or otherwise clear from context, phrase “based on” means “based at least in part on” and not “based solely on.”

Operations of processes described herein can be performed in any suitable order unless otherwise indicated herein or otherwise clearly contradicted by context. In at least one embodiment, a process such as those processes described herein (or variations and/or combinations thereof) is performed under control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in form of a computer program comprising a plurality of instructions executable by one or more processors. In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause computer system to perform operations described herein. A set of non-transitory computer-readable storage media, in at least one embodiment, comprises multiple non-transitory computer-readable storage media and one or more of individual non-transitory storage media of multiple non-transitory computer-readable storage media lack all of code while multiple non-transitory computer-readable storage media collectively store all of code. In at least one embodiment, executable instructions are executed such that different instructions are executed by different processors-for example, a non-transitory computer-readable storage medium store instructions and a main central processing unit (“CPU”) executes some of instructions while a graphics processing unit (“GPU”) executes other instructions. In at least one embodiment, different components of a computer system have separate processors and different processors execute different subsets of instructions.

Accordingly, in at least one embodiment, computer systems are configured to implement one or more services that singly or collectively perform operations of processes described herein and such computer systems are configured with applicable hardware and/or software that enable performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

Use of any and all examples, or exemplary language (e.g., “such as”) provided herein, is intended merely to better illuminate embodiments of disclosure and does not pose a limitation on scope of disclosure unless otherwise claimed. No language in specification should be construed as indicating any non-claimed element as essential to practice of disclosure.

In description and claims, terms “coupled” and “connected,” along with their derivatives, may be used. It should be understood that these terms may be not intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other, but yet still co-operate or interact with each other.

Unless specifically stated otherwise, it may be appreciated that throughout specification terms such as “processing,” “computing,” “calculating,” “determining,” or like, refer to action and/or processes of a computer or computing system, or similar electronic computing device, that manipulate and/or transform data represented as physical, such as electronic, quantities within computing system's registers and/or memories into other data similarly represented as physical quantities within computing system's memories, registers or other such information storage, transmission or display devices.

In a similar manner, term “processor” may refer to any device or portion of a device that processes electronic data from registers and/or memory and transform that electronic data into other electronic data that may be stored in registers and/or memory. As non-limiting examples, “processor” may be a CPU or a GPU. A “computing platform” may comprise one or more processors. As used herein, “software” processes may include, for example, software and/or hardware entities that perform work over time, such as tasks, threads, and intelligent agents. Also, each process may refer to multiple processes, for carrying out instructions in sequence or in parallel, continuously or intermittently. Terms “system” and “method” are used herein interchangeably insofar as system may embody one or more methods and methods may be considered a system.

In present document, references may be made to obtaining, acquiring, receiving, or inputting analog or digital data into a subsystem, computer system, or computer-implemented machine. Obtaining, acquiring, receiving, or inputting analog and digital data can be accomplished in a variety of ways such as by receiving data as a parameter of a function call or a call to an application programming interface. In some implementations, process of obtaining, acquiring, receiving, or inputting analog or digital data can be accomplished by transferring data via a serial or parallel interface. In another implementation, process of obtaining, acquiring, receiving, or inputting analog or digital data can be accomplished by transferring data via a computer network from providing entity to acquiring entity. References may also be made to providing, outputting, transmitting, sending, or presenting analog or digital data. In various examples, process of providing, outputting, transmitting, sending, or presenting analog or digital data can be accomplished by transferring data as an input or output parameter of a function call, a parameter of an application programming interface or interprocess communication mechanism.

Although discussion above sets forth example implementations of described techniques, other architectures may be used to implement described functionality, and are intended to be within scope of this disclosure. Furthermore, although specific distributions of responsibilities are defined above for purposes of discussion, various functions and responsibilities might be distributed and divided in different ways, depending on circumstances.

Furthermore, although subject matter has been described in language specific to structural features and/or methodological acts, it is to be understood that subject matter claimed in appended claims is not necessarily limited to specific features or acts described. Rather, specific features and acts are disclosed as exemplary forms of implementing the claims.

What is claimed is:

1. A system, comprising:
a network switch;
one or more layered circuit boards to receive inputs to be provided to the network switch;
one or more layered cable sets to connect corresponding ones of the one or more layered circuit boards and the network switch; and
one or more layers of a routing cartridge to route corresponding ones of the one or more layered cable sets between the corresponding one or more layered circuit boards and the network switch.

2. The system of claim 1, wherein the one or more layered circuit boards are attached to the routing cartridge.

3. The system of claim 1, further comprising:
a plurality of ports, located on the one or more layered circuit boards, to connect with external devices that provide at least some of the inputs.

4. The system of claim 1, wherein at least one of the cable sets are within a harness.

5. The system of claim 1, further comprising:
one or more devices to provide liquid cooling or air cooling for at least a portion of the network switch and for at least a portion of the one or more layered circuit boards.

6. The system of claim 5, wherein the one or more devices provide liquid cooling and are adjacent, between the one or more layered circuit boards and the network switch, to at least a portion of the routing cartridge.

7. The system of claim 5, wherein the one or more devices provide air-cooling and the routing cartridge includes at least one opening to allow airflow from the device to pass between the one or more layered circuit boards and the network switch.

8. The system of claim 1, wherein the one or more layered cable sets connect with one or more devices of the network switch.

9. A method comprising:
receiving, along one or more paths of a composite routing cartridge, a plurality of cables having opposing ends extending out from the composite routing cartridge;
securing the plurality of cables to the composite routing cartridge; and
providing the plurality of cables secured to the composite routing cartridge for a network connection.

10. The method of claim 9, further comprising:
connecting a first end of at least a portion of the plurality of cables to a front section of a server assembly; and
connecting a second end of at least the portion of the plurality of cables to a rear section of a server assembly.

11. The method of claim 10, wherein the first end is connected to the front section of the server assembly before the plurality of cables are received along the one or more paths.

12. The method of claim 10, further comprising:
color coding a first end and a second end of at least a portion of the plurality of cables.

13. The method of claim 9, wherein the composite routing cartridge includes two or more separate sections having fixtures to retain portions of the plurality of cables to the individual sections.

14. The method of claim 9, wherein one or more of the paths are positioned at least partially in separate parallel layers.

15. The method of claim 9, wherein one or more of the paths are across two or more perpendicular planes.

16. A network cable management device comprising:
a variety of modular pieces combinable to change grouping and orientation between one or more planes for at least a portion of a plurality of network cables, positioned through the variety of modular pieces, when combining the variety of modular pieces.

17. The network cable management device of claim 16, wherein the plurality of network cables are positioned into the variety of modular pieces, from a stack of printed circuit board (PCB) cards, on a plurality of parallel planes.

18. The network cable management device of claim 16, further comprising:
at least one additional modular piece combinable with the variety of modular pieces to maintain at least one grouping or orientation change.

19. The network cable management device of claim 16, the variety of modular pieces further comprising:
one or more sections to be affixed to a network device connected to at least one of the plurality of network cables.

20. The network cable management device of claim 16, wherein the variety of modular pieces include one or more openings to allow airflow to pass through the network cable management device and the one or more opening separate from the plurality of network cables.

21. The network cable management device of claim 16, wherein one or more of the variety of modular pieces comprise reinforced plastic.

22. A system, comprising:
a network including a network switch and a plurality of layered transceiver panel structures, wherein the plurality of layered transceiver panel structures further comprises:
one or more transceiver cages including a plurality of transceivers to communicably couple the network switch with the plurality of layered transceiver panel structures; and
one or more structural supports between at least two layers of the plurality of layered transceiver panel structures.
